(19) United States
(12) Patent Application Publication
(10) Pub. No.: US 2026/0040622 A1
(43) Pub. Date: Feb. 5, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Chun-Yi CHOU, Hsinchu City (TW); Chih-Chao CHOU, Hsinchu City (TW); Guan-Lin CHEN, Baoshan Township (TW); Kuo-Cheng CHIANG, Zhubei City (TW); Chih-Hao WANG, Baoshan Township (TW)

(73) Assignee: Taiwan Semiconductor Manufacturing Company, Ltd., Hsinchu (TW)

(21) Appl. No.: 18/793,426

(22) Filed: Aug. 2, 2024

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6713; H10D 30/6757; H10D 62/121; H10D 64/017

(57) ABSTRACT

A method of forming a semiconductor structure includes forming a fin structure including first and second semiconductor layers that are alternately stacked; forming a dummy gate structure on the fin structure; and forming source/drain trenches on opposite sides of the dummy gate structure. The method further includes removing the first semiconductor layers through the source/drain trenches to form cavities; epitaxially growing epitaxial layers on surfaces of the second semiconductor layers exposed in the cavities; and forming dielectric layers to fill the cavities, such that the dielectric layers are between the second semiconductor layers, between the substrate and the bottommost second semiconductor layer, and over the topmost second semiconductor layer. The method further includes removing the dummy gate structure to form a gate trench; trimming the second semiconductor layers and the dielectric layers through the gate trench; and forming a gate structure in the gate trench.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As IC technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. While existing GAA transistors may be generally adequate for their intended purposes, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2A and 2B are perspective views of a workpiece at various fabrication stages, in accordance with some embodiments of the present disclosure.

FIGS. 3A, 4A, 5A, 6A, 7A, 8A, 9A, 10A, 11A, 12A, 13A, 14A, 15A, 16A, 17A, 18A, and 19A are X-Z cross-sectional views of the workpiece at various fabrication stages along a line A-A′ of FIG. 2A, in accordance with some embodiments of the present disclosure.

FIGS. 3B, 4B, 5B, 6B, 7B, 8B, 9B, 10B, 11B, 12B, 13B, 14B, 15B, 16B, 17B, 18B, and 19B are Y-Z cross-sectional views of the workpiece at various fabrication stages along a line B-B′ of FIG. 2A, in accordance with some embodiments of the present disclosure.

FIGS. 3C, 4C, 5C, 6C, 7C, 8C, 9C, 10C, 11C, 12C, 13C, 14C, 15C, 16C, 17C, 18C, and 19C are X-Z cross-sectional views of the workpiece at various fabrication stages along a line C-C′ of FIG. 2B, in accordance with some embodiments of the present disclosure.

FIGS. 3D, 4D, 5D, 6D, 7D, 8D, 9D, 10D, 11D, 12D, 13D, 14D, 15D, 16D, 17D, 18D, and 19D are Y-Z cross-sectional views of the workpiece at various fabrication stages along a line D-D′ of FIG. 2B, in accordance with some embodiments of the present disclosure.

FIG. 19E is a Y-Z cross-sectional view of the workpiece at a fabrication stage along a line E-E′ of FIG. 2A, in accordance with some embodiments of the present disclosure.

FIG. 19F is a Y-Z cross-sectional view of the workpiece at a fabrication stage along a line F-F′ of FIG. 2B, in accordance with some embodiments of the present disclosure.

FIG. 19G is a partial enlarged cross-sectional views of the workpiece of FIG. 19D, in accordance with some embodiments of the present disclosure.

FIG. 20 is a Y-Z cross-sectional view of the workpiece at a fabrication stage along a line G-G′ of FIG. 19C, in accordance with some embodiments of the present disclosure.

FIG. 21 is a schematic layout of an exemplary standard cell, in accordance with some embodiments of the present disclosure.

FIG. 22 is a schematic layout of an exemplary static random access memory (SRAM) cell, in accordance with some embodiments of the present disclosure.

FIG. 23 is a schematic layout of an exemplary SRAM cell, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors. Generally, a GAA transistor may include a plurality of vertically stacked nanostructures (e.g., nanosheets, nanowires, or nanorods) in a channel region of the transistor, thereby allowing better gate control, lowered leakage current, and improved scaling capability for various IC applications.

The nanostructure transistor (e.g., nanosheet transistor, nanowire transistor, multi-bridge channel, nano-ribbon FET, GAA transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In IC layout, there is a great amount of transistors, and the different transistors may quest for different performance indexes. For example, first type of transistors quest for higher on-current, and thus active regions with wider width are provided for these transistors. On the other hand, for second type of transistors, the high on-current is not a main concern, and thus the on-current can be used to trade off against other performance indexes, such as device density. Therefore, the second type of transistors can accept active regions with narrower width to increase the number of active regions in a given area, thereby increasing the device density. However, there is a limit to the scaling down of the active regions. Therefore, a novel structure and fabricating method are needed to reduce the width of the active regions, so as to increase the device density further.

Embodiments of the present disclosure offer advantages over the existing art, though it is understood that other embodiments may offer different advantages, not all advantages are necessarily discussed herein, and no particular advantage is required for all embodiments. For example, embodiments discussed herein include structures and methods that include a trimming process to reduce the width of active region, thereby increasing the device density and improving power efficiency (i.e., reducing power consumption). Moreover, embodiments discussed herein include structures and methods that include an additional epitaxial growth process to grow additional epitaxial layers on nanostructures to increase the areas of the nanostructures in a vertical direction, so as to compensate the on-current decreased in the trimming process. The increased areas of the nanostructures also improve the quality of source/drain features epitaxially grown from the nanostructures, so that the source/drain features can be fully strained, especially in p-type FET. Further, embodiments discussed herein include structures and methods that include forming dielectric layers between the nanostructures to reduce the area of metal gate equivalently, which can reduce the parasitic capacitance.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

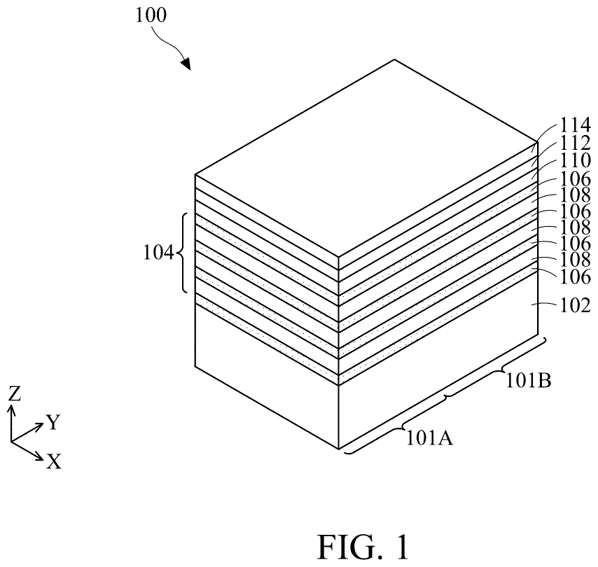

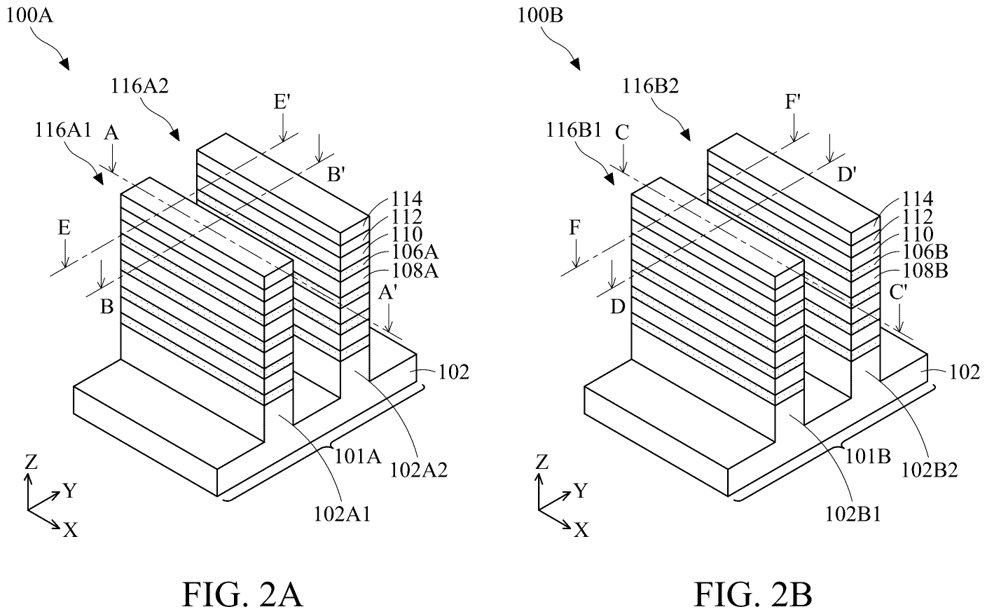

FIGS. 1, 2A and 2B are perspective views of a workpiece 100 at various fabrication stages, in accordance with some embodiments of the present disclosure. Referring to FIG. 1, the workpiece 100 is provided. The workpiece 100 includes a substrate 102 and a stack 104 over the substrate 102. In some embodiments, the substrate 102 contains a semiconductor material, such as bulk silicon (Si). In some embodiments, the substrate 102 may include other semiconductors such as germanium (Ge), silicon germanium (SiGe), or a III-V semiconductor material. Example III-V semiconductor materials may include GaAs, InP, GaP, GaN, GaAsP, AlInAs, AlGaAs, GaInP, and InGaAs. The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions for forming different types of devices. For example, the well regions may be n-type well regions doped with an n-type dopant (e.g., phosphorus (P) or arsenic (As)) or p-type well regions doped with a p-type dopant (e.g., boron (B) or indium (In)). The n-type and p-type well regions may be formed by using ion implantation or thermal diffusion. Since the workpiece 100 will be fabricated into a semiconductor structure 100 upon conclusion of the fabrication processes, the workpiece 100 may be referred to as the semiconductor structure 100 as the context requires.

The stack 104 may include semiconductor layers 106 and semiconductor layers 108. In some embodiments, the semiconductor layers 106 and the semiconductor layers 108 are alternatingly stacked in the Z-direction. The semiconductor layers 106 and the semiconductor layers 108 may have different semiconductor compositions. In some embodiments, the semiconductor layers 106 are formed of silicon germanium (SiGe), and the semiconductor layers 108 are formed of silicon (Si). In these embodiments, the additional germanium content in the semiconductor layers 106 allows selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over or on the substrate 102 using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 106 and the semiconductor layers 108 are deposited alternatingly, one-after-another, to form the stack 104. It should be noted that, four layers of the semiconductor layers 106 and three layers of the semiconductor layers 108 are alternately and vertically arranged (or stacked) as shown in FIG. 1, which are for illustrative purposes only and are not intended to be limiting beyond what is specifically recited in the claims. The number of layers depends on the desired number of channel members for the semiconductor device. In some embodiments, there may be from 3 to 10 semiconductor layers 106 alternating with 2 to 10 semiconductor layers 108 in the stack 104.

For patterning purposes, the workpiece 100 may also include a hard mask layer structure over the stack 104. The hard mask structure may be a multi-layer structure and includes, for example, a hard mask 110, a hard mask 112 over the hard mask 110, and a hard mask 114 over the hard mask 112. In some embodiments, the hard mask 110 includes SiCN, the hard mask 112 includes nitride (e.g., SiN), and the hard mask 114 includes oxide.

Referring to FIGS. 2A and 2B, the workpiece 100 is formed into semiconductor structures 100A and 100B, in accordance with some embodiments of the present disclosure. In some embodiments, the semiconductor structure 100A is formed in the region 101A of the workpiece 100, and the semiconductor structure 100B is formed in the region 101B of the workpiece 100. In some embodiments, the substrate 102, the stack 104, and the hard masks 110-114 are patterned to form fin structures 116A1 and 116A2 of the semiconductor structure 100A in the region 101A, and form fin structures 116B1 and 116B2 of the semiconductor structure 100B in the region 101B, as shown in FIGS. 2A and 2B.

In some embodiments, in the semiconductor structure 100A, each of the fin structures 116A1 and 116A2 includes a base portion (base fins 102A1 and 102A2) formed from a portion of the substrate 102 and a stack portion formed from the stack 104 over the base portion, as shown in FIG. 2A. The stack portion includes the semiconductor layers 106A and the semiconductor layers 108A alternately stacked over the substrate 102, wherein the semiconductor layers 106A and 108A are formed from the semiconductor layers 106 and 108, respectively. In some embodiments, the base fins 102A1 and 102A2 protrude from the substrate 102. Each of the fin structures 116A1 and 116A2 extends lengthwise in the X-direction and extends vertically in the Z-direction over the substrate 102, and arranged in the Y-direction. Although the two fin structures 116A1 and 116A2 are formed and shown herein, more fin structures may be formed, such as three or more fin structures.

In some embodiments, in the semiconductor structure 100B, each of the fin structures 116B1 and 116B2 includes a base portion (base fins 102B1 and 102B2) formed from a portion of the substrate 102 and a stack portion formed from the stack 104 over the base portion, as shown in FIG. 2B. The stack portion includes the semiconductor layers 106B and the semiconductor layers 108B alternately stacked over the substrate 102, wherein the semiconductor layers 106B and 108B are formed from the semiconductor layers 106 and 108, respectively. In some embodiments, the base fins 102B1 and 102B2 protrude from the substrate 102. Each of the fin structures 116B1 and 116B2 extends lengthwise in the X-direction and extends vertically in the Z-direction over the substrate 102, and arranged in the Y-direction. Although the two fin structures 116B1 and 116B2 are formed and shown herein, more fin structures may be formed, such as three or more fin structures.

In some embodiments, the widths of the active regions of the devices (e.g., GAA transistors) formed from the semiconductor structure 100A are greater than or equal to the widths of the active regions of the devices (e.g., GAA transistors) formed from the semiconductor structure 100B. For example, in the Y-direction, the semiconductor layers 106A and 108A and the base fins 102A1 and 102A2 have a width in a range from about 8 nanometers (nm) to about 13 nm or a width greater than about 16 nm, and the semiconductor layers 106B and 108B and the base fins 102B1 and 102B2 have a width in a range from about 8 nm to about 13 nm. In some embodiments, at the fabrication stage shown in FIGS. 2A and 2B, in the Z-direction, each of the semiconductor layers 106A and 106B has a thickness in a range from about 3.5 nm to about 6 nm, and each of the semiconductor layers 108A and 108B has a thickness in a range from about 8 nm to about 11 nm.

The fin structures 116A1, 116A2, 116B1, and 116B2 (may be collectively referred to as fin structures 116) may be patterned using suitable processes including photolithography processes and etching processes. The suitable processes may include double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fin structures 116 by etching the stack 104 and the substrate 102. The etching process may include dry etching, wet etching, reactive ion etching (RIE), and/or other suitable processes. In some embodiments, the photolithography processes include photoresist coating (e.g., spin-on coating), soft baking, mask aligning, exposure, post-exposure baking, developing the photoresist, rinsing, and drying (e.g., hard baking). In some other embodiments, the photolithography processes may be implemented or replaced by other suitable methods, such as maskless photolithography, electron-beam (e-beam) writing, and ion-beam writing.

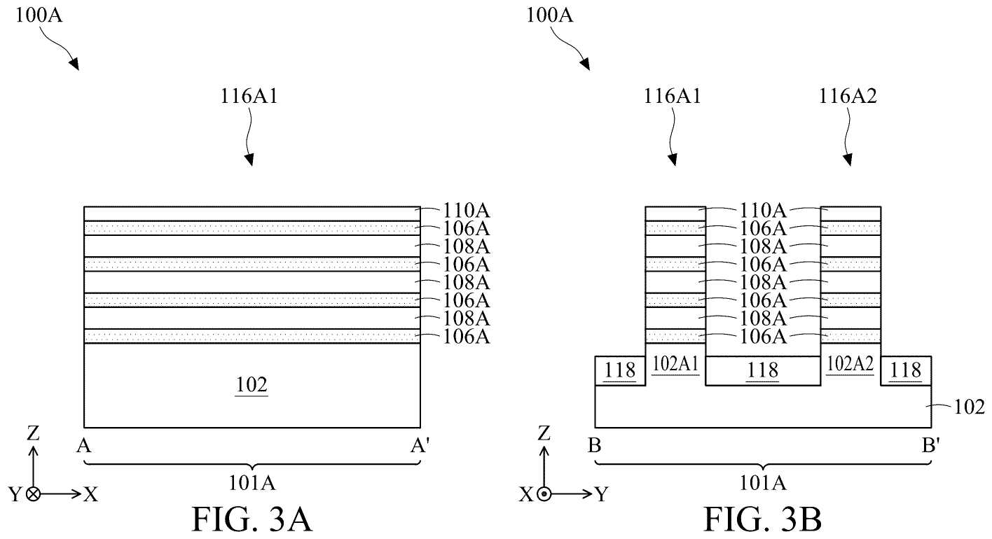

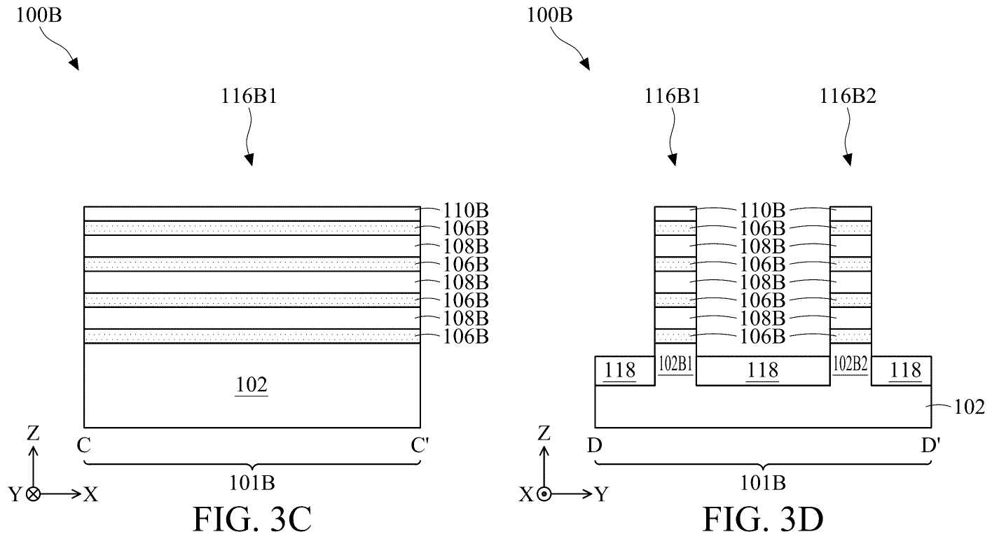

Referring to FIGS. 3A to 3D, isolation structures 118 are formed, in accordance with some embodiments. FIGS. 3A and 3B are cross-sectional views of the semiconductor structure 100A along lines A-A′ and B-B′ of FIG. 2A, respectively. FIGS. 3C and 3D are cross-sectional views of the semiconductor structure 100B along lines C-C′ and D-D′ of FIG. 2B, respectively. After the fin structures 116 are formed, the hard masks 110 to 114 over the fin structures 116 are partially removed, and the isolation structures 118 are formed over the substrate 102. In some embodiments, the hard masks 112 and 114 are removed, and the hard mask 110 is remained or partially remained. The hard mask 110 remained in the fin structures 116A1 and 116A2 may be referred to as hard masks 110A, and the hard mask 110 remained in the fin structures 116B1 and 116B2 may be referred to as hard masks 110B, as shown in FIGS. 3A to 3D. In some embodiments, the isolation structures 118 are formed between the fin structures 116. In other embodiments, the isolation structures 118 are formed around the fin structures 116. More specifically, the isolation structures 118 are formed between and around the base fins (e.g., base fins 102A1, 102A2, 102B1, and 102B2) of the fin structures 116. The isolation structures 118 may also be referred to as shallow trench isolation (STI) features.

In some embodiments, a dielectric material for the isolation structures 118 is first deposited over the workpiece 100. Specifically, the dielectric material is deposited and formed over the fin structures 116 and the substrate 102 to cover the fin structures 116 and the substrate 102. In some embodiments, the dielectric material is formed to wrap around the fin structures 116. In some embodiments, the dielectric material may include silicon oxide (SiO₂), silicon nitride (Si₃N₄), silicon oxynitride (SiON), fluorine-doped silicate glass (FSG), a low-k dielectric material, other suitable materials, or combinations thereof. Exemplary low-k dielectric materials include carbon doped silicon oxide, xerogel, aerogel, amorphous fluorinated carbon, parylene, BCB-based dielectric material, polyimide, other low-k dielectric materials, or combinations thereof.

In some embodiments, the dielectric material may be deposited using a deposition process, such as CVD, subatmospheric CVD (SACVD), flowable CVD (FCVD), ALD, spin-on coating, and/or other suitable process. The deposited dielectric material is then thinned and planarized, for example by a chemical mechanical polishing (CMP) process, until the top surfaces of the hard masks 114 are exposed (not shown). The planarized dielectric material is further recessed by a dry etching process, a wet etching process, or a combination thereof to form the isolation structures 118. In some embodiments, before the formation of the isolation structures 118, a liner layer may be conformally deposited over the substrate 102 using a deposition process, such as CVD, ALD, high-density plasma CVD (HDPCVD), MOCVD, RPCVD, plasma-enhanced CVD (PECVD), LPCVD, atomic layer CVD (ALCVD), atmospheric pressure CVD (APCVD), FCVD, or combinations thereof.

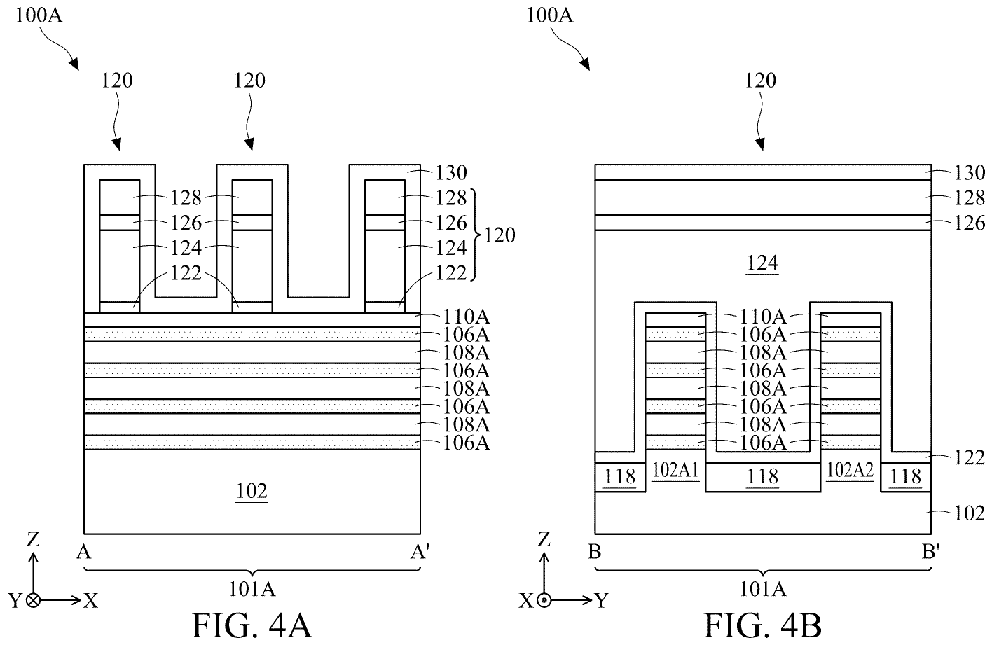

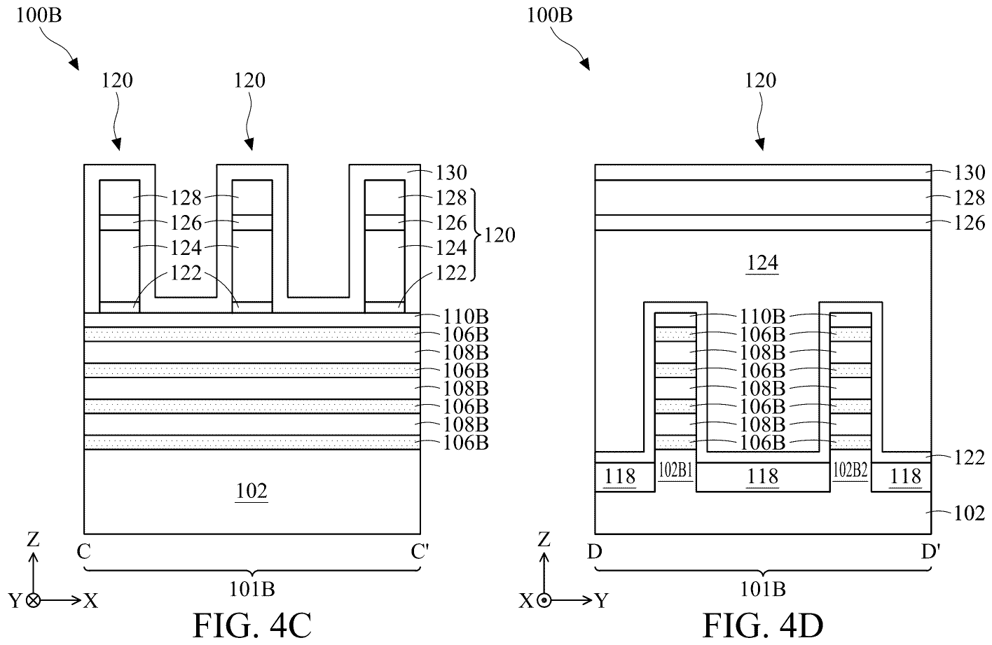

Referring to FIGS. 4A to 4D, dummy gate structures 120 may be formed over the fin structures 116 and over the isolation structure 118, in accordance with some embodiments. FIGS. 4A and 4B are cross-sectional views of the semiconductor structure 100A along lines A-A′ and B-B′ of FIG. 2A, respectively. FIGS. 4C and 4D are cross-sectional views of the semiconductor structure 100B along lines C-C′ and D-D′ of FIG. 2B, respectively.

In some embodiments, the dummy gate structures 120 may be configured to extend lengthwise in the Y-direction and wrap around top surfaces and side surfaces of the fin structures 116. In some embodiments, in order to form the dummy gate structures 120, a dummy gate dielectric material for dummy gate dielectric layers 122 is first formed over the fin structures 116 and over the isolation structure 118. In some embodiments, the dummy gate dielectric layer 122 may include, a dielectric material such as a nitride (e.g., SiN, SiON), a carbide (e.g., SiC), an oxide (e.g., SiO₂), or some other suitable materials.

Then, in some embodiments, a dummy gate electrode material for dummy gate electrode layers 124 is formed over the dummy gate dielectric material. The dummy gate electrode material may include a conductive material selected from a group composed of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., physical vapor deposition (PVD), CVD, PECVD, and ALD).

Afterward, hard masks 126 and 128 are formed over the dummy gate electrode material. In some embodiments, the hard masks 126 and 128 may be formed using photolithography and etching processes. In some embodiments, the hard masks 126 and 128 may include photoresist materials or hard mask materials. In some embodiments, the hard mask 126 may be a silicon nitride layer and the hard mask 128 may be a silicon oxide layer. After the formation of the hard masks 126 and 128, a removal process (e.g., etching) may be performed to remove portions of the dummy gate electrode material for the dummy gate electrode layers 124 and the dummy gate dielectric material for the dummy gate dielectric layers 122 that are not directly underlie the hard masks 126 and 128, thereby forming the dummy gate structures 120. Each of the dummy gate structures 120 has the dummy gate dielectric layer 122, the dummy gate electrode layer 124, and the hard masks 126 and 128. The dummy gate dielectric layers 122 may also be referred to as dummy interfacial layers.

The dummy gate structures 120 may undergo a gate replacement process through subsequent processing to form metal gates, such as a high-k metal gate, as discussed in greater detail below. FIGS. 4A and 4C show that each the semiconductor structures 100A and 100B has three dummy gate structures 120. In some embodiments, in the semiconductor structures 100A and 100B, less or more dummy gate structures may be formed for one or more transistors sharing source/drain regions.

Still referring to FIGS. 4A to 4D, after the formation of the dummy gate structures 120, spacer layers 130 for gate spacers (e.g., gate spacers 132A and 132B discussed below) are conformally deposited over the fin structures 116 and the dummy gate structures 120, in accordance with some embodiments. In some embodiments, the spacer layers 130 are formed over the top surfaces of the hard masks 110A and 110B, as shown in FIGS. 4A and 4C. The spacer layers 130 may be formed by CVD, PVD, ALD, HDPCVD, MOCVD, RPCVD, PECVD, LPCVD, ALCVD, APCVD, FCVD, or other suitable methods. The spacer layers 130 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), carbon doped oxide, nitrogen doped oxide, porous oxide, or combinations thereof. In some embodiments, the spacer layers 130 include a low-k dielectric material, such as those described herein. The spacer layers 130 may include a single layer or a multi-layer structure.

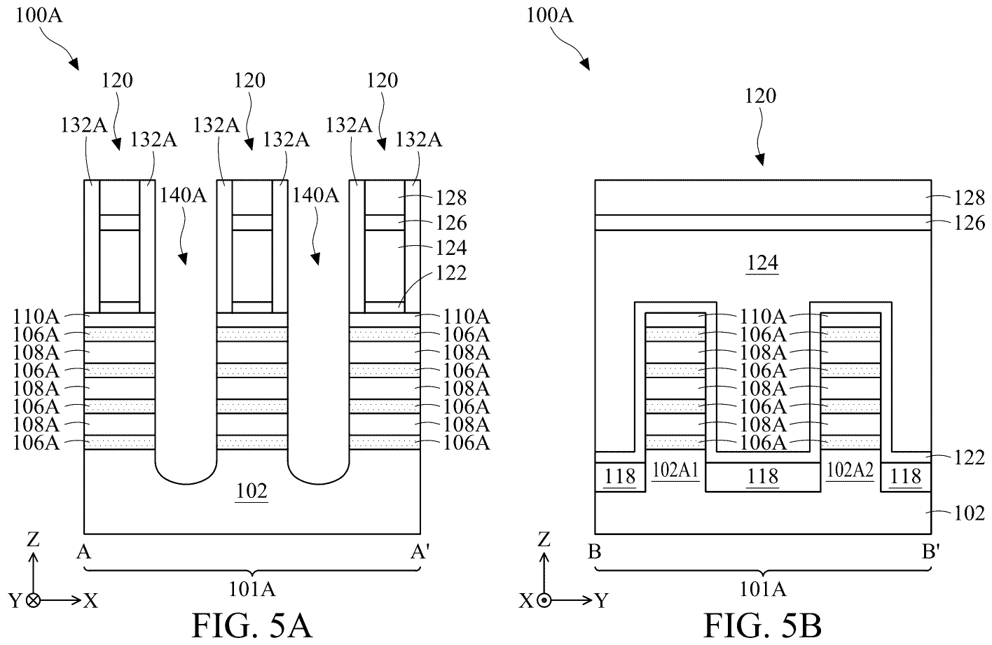

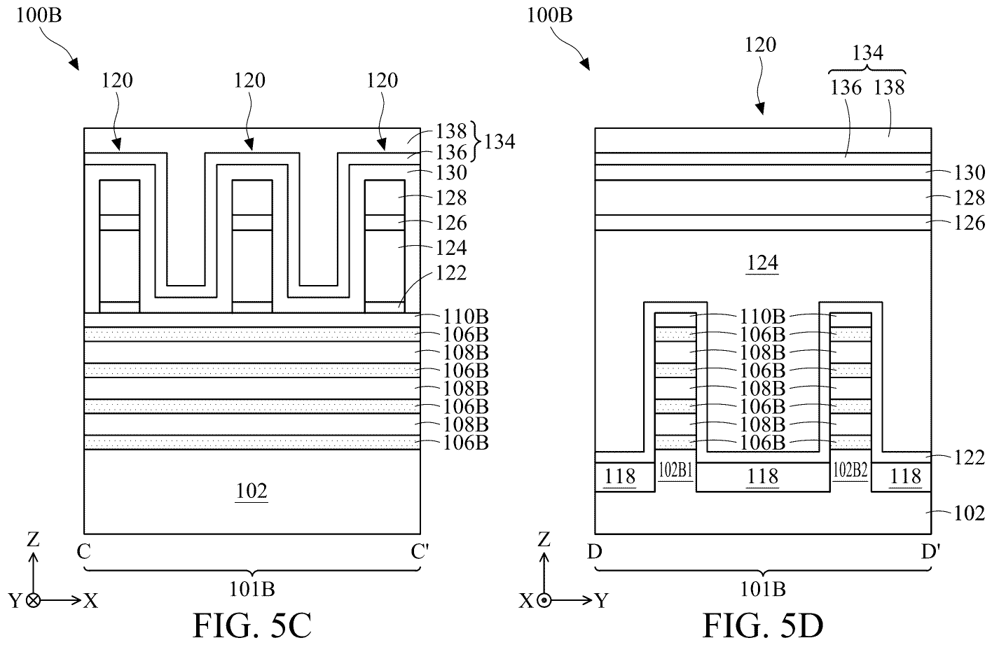

Referring to FIGS. 5A to 5D, a patterned mask 134 is formed to cover semiconductor structure 100B while remaining the semiconductor structure 100A exposed, in accordance with some embodiments. FIGS. 5A and 5B are cross-sectional views of the semiconductor structure 100A along lines A-A′ and B-B′ of FIG. 2A, respectively. FIGS. 5C and 5D are cross-sectional views of the semiconductor structure 100B along lines C-C′ and D-D′ of FIG. 2B, respectively.

The patterned mask 134 may be formed to have a sufficiently great thickness (or height) such that the top surface and sidewalls of the semiconductor structure 100B are fully covered, as shown in FIGS. 5C and 5D. Formation of the patterned mask 134 may allow one or more processes to be performed on the semiconductor structure 100A only. The patterned mask 134 may include a first mask 136 and a second mask 138 over the first mask 136, as shown in FIGS. 5C and 5D. In some embodiments, the first mask 136 includes nitride, and the second mask 138 includes photoresist.

Still referring to FIGS. 5A to 5D, gate spacers 132A are formed on sidewalls of the dummy gate structures 120 of the semiconductor structure 100A, and over the top surfaces and on the sidewalls of the fin structures 116A1 and 116A2, in accordance with some embodiments. In some embodiments, an anisotropic etching process is performed to remove horizontal portions of the spacer layer 130 from the top surfaces of the fin structures 116A1 and 116A2 and the dummy gate structures 120 in the region 101A. After the anisotropic etching process, in the region 101A, the portions of the spacer layer 130 on sidewall surfaces of the fin structures 116A1 and 116A2 and the dummy gate structures 120 substantially remain and become the gate spacers 132A. In some embodiments, the anisotropic etching process is a dry (e.g., plasma) etching process.

Still referring to FIGS. 5A to 5D, the fin structures 116A1 and 116A2 are recessed to form source/drain trenches in the fin structures 116A1 and 116A2 (or passing through semiconductor layers 106A and 108A and the hard mask 110A) for source/drain regions of the semiconductor structure 100A, in accordance with some embodiments. In some embodiments, in the semiconductor structure 100A, the source/drain trenches 140A are formed on opposite sides of the dummy gate structures 120 in the X-direction. Specifically, the source/drain trenches 140A may be formed by performing one or more etching processes to remove portions of the hard mask 110A, the semiconductor layers 106A and 108A, and the substrate 102 (e.g., base fins 102A1 and 102A2) that do not vertically overlap or not be covered by the dummy gate structures 120 and the gate spacers 132A.

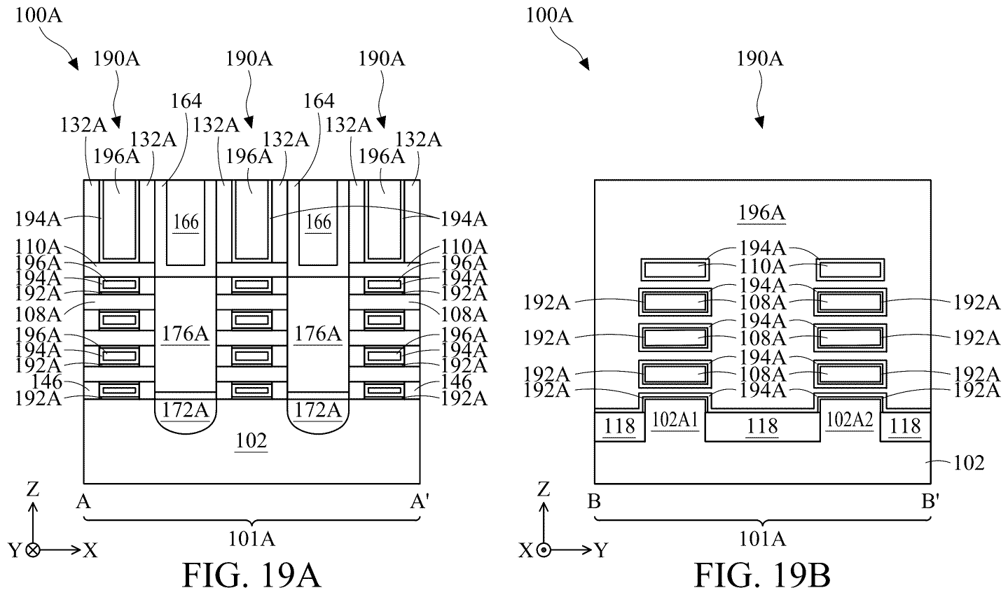

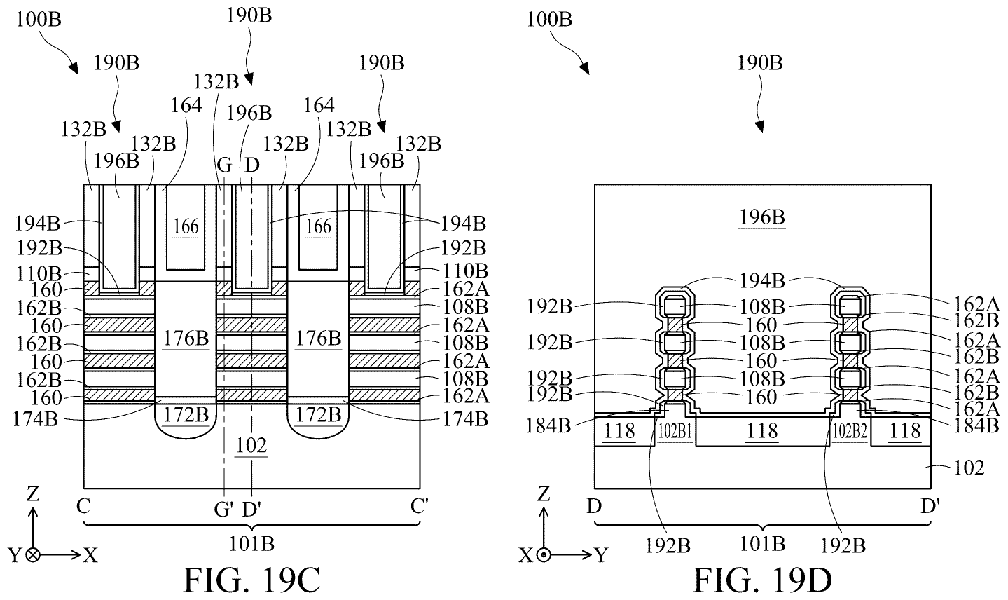

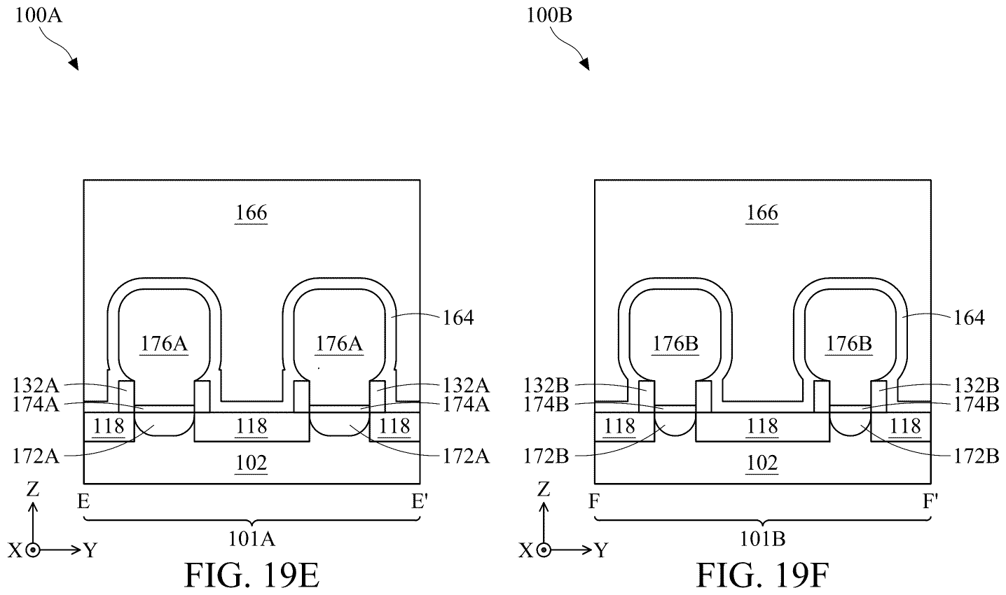

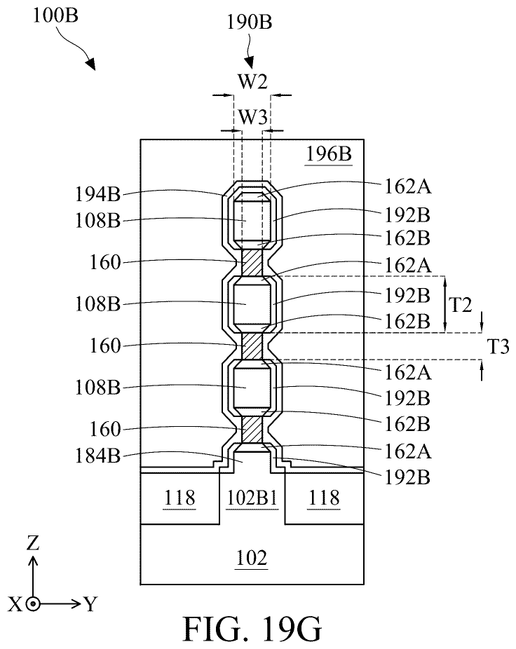

In some embodiments, a single etchant may be used to remove the hard mask 110A, the semiconductor layers 106A and 108A, and the substrate 102. In other embodiments, multiple etchants may be used to perform the etching process. In some embodiments, portions of the substrate 102 are etched, so that the source/drain trenches 140A extend into the substrate and each has a concave surface in the substrate 102, as shown in FIG. 5A. In some embodiments, portions of the gate spacers 132A on opposite sidewalls of the fin structures 116A1 and 116A2 in the Y-direction are removed. In these embodiments, the height of the gate spacers 132A on opposite sidewalls of the fin structures 116A1 and 116A2 in the Y-direction are reduced (see FIG. 19E below).

In some embodiments, the formation of the gate spacers 132A and the formation of the source/drain trenches 140A are performed in the same etching process. In some embodiments, during the formation of the gate spacers 132A and the formation of the source/drain trenches 140A, the semiconductor structure 100B may remain covered by the patterned mask 134, which allows semiconductor structure 100B to remain intact.

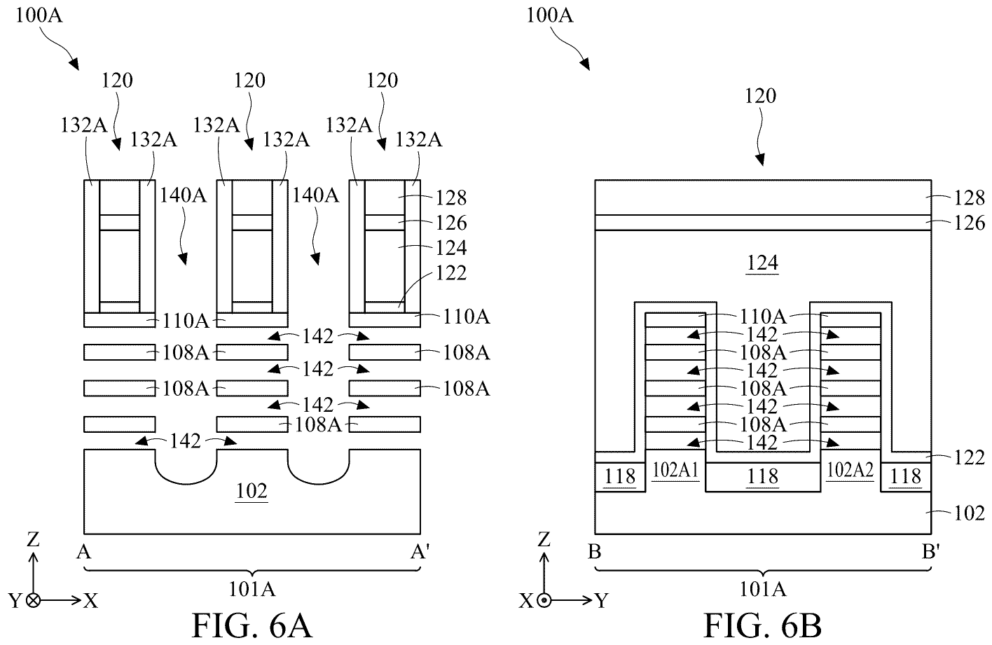

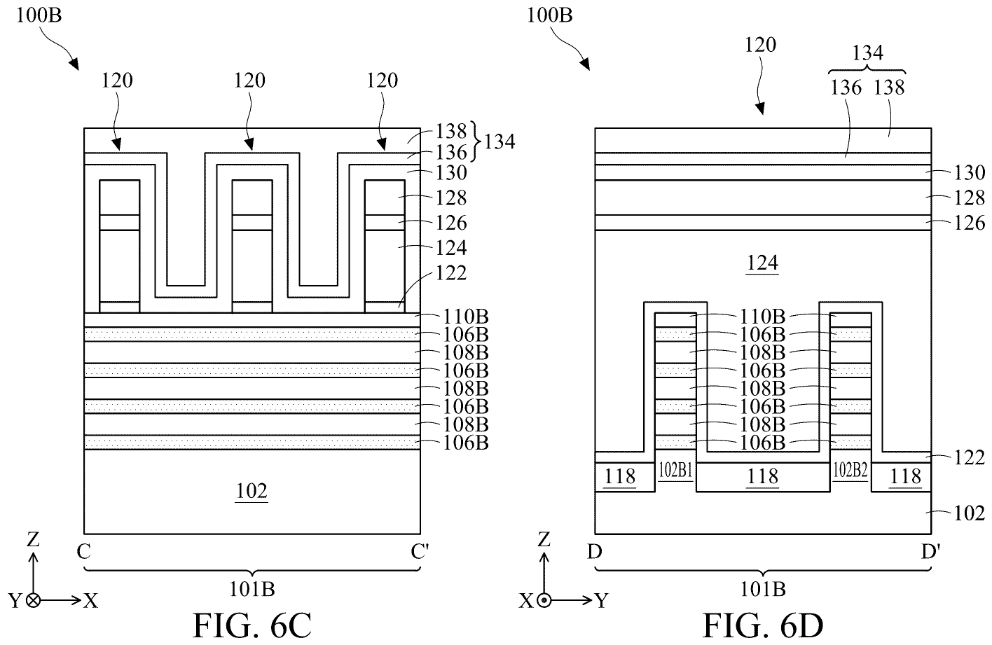

Referring to FIGS. 6A to 6D, the semiconductor layers 106A are removed through the source/drain trenches 140A to form cavities 142, in accordance with some embodiments. FIGS. 6A and 6B are cross-sectional views of the semiconductor structure 100A along lines A-A′ and B-B′ of FIG. 2A, respectively. FIGS. 6C and 6D are cross-sectional views of the semiconductor structure 100B along lines C-C′ and D-D′ of FIG. 2B, respectively.

In some embodiments, in the region 101A, the semiconductor layers 106A exposed in the source/drain trenches 140A are removed through a selective etching process, and the semiconductor layers 108A are not etched. More specifically, the selective etching process is performed that selectively etches the semiconductor layers 106A through the source/drain trenches 140A, with minimal etching (or substantially no etching) of the hard mask 110A, the semiconductor layers 108A, and the substrate 102. After the selective etching process, the cavities 142 are vertically formed between the hard masks 110A and the semiconductor layers 108A, between the semiconductor layers 108A, between the semiconductor layers 108A and the substrate 102, and below the dummy gate structures 120 and the gate spacers 132A. The selective etching process may be a dry etching process, a wet etching process, other suitable etching process, or a combination thereof. In some embodiments, all of the semiconductor layers 106A are removed. In some embodiments, during the removal of the semiconductor layers 106A and the formation of the cavities 142, the semiconductor structure 100B may remain covered by the patterned mask 134, which allows semiconductor structure 100B to remain intact.

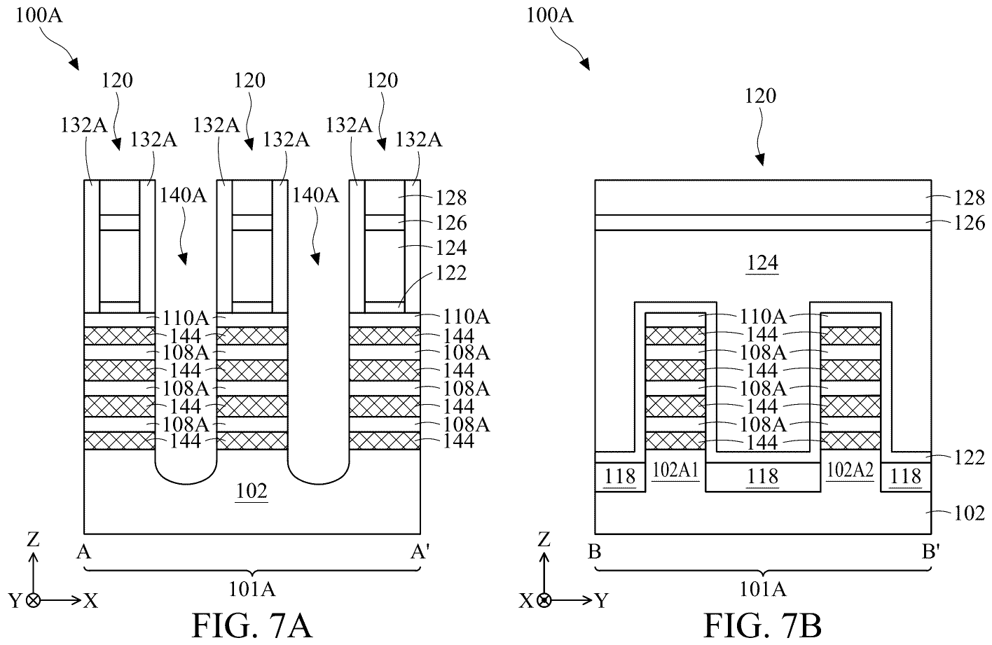

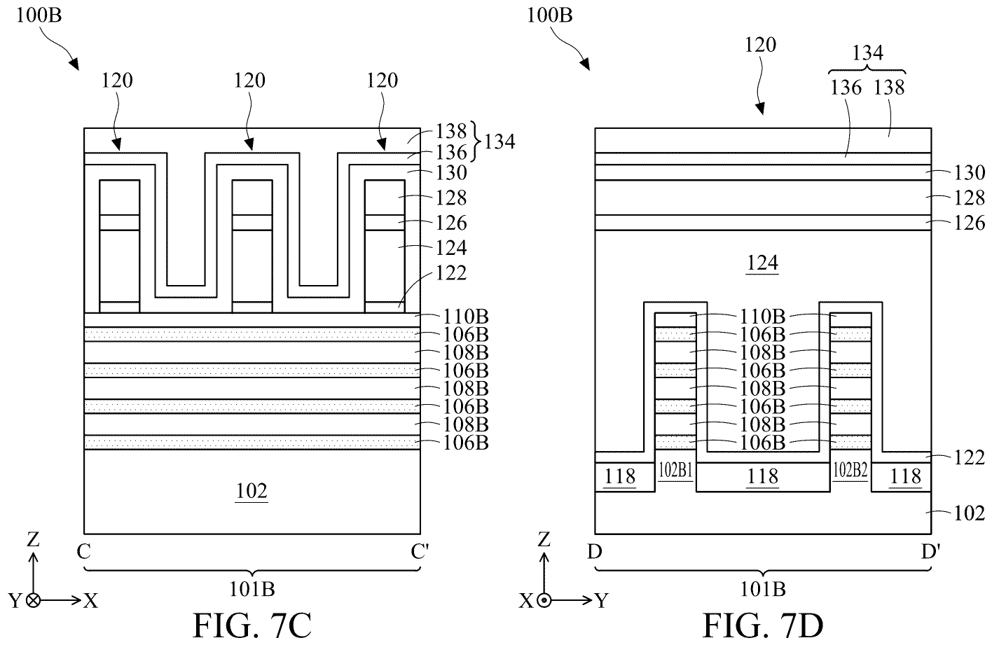

Referring to FIGS. 7A to 7D, dielectric interposers 144 are formed in the cavities 142, in accordance with some embodiments. FIGS. 7A and 7B are cross-sectional views of the semiconductor structure 100A along lines A-A′ and B-B′ of FIG. 2A, respectively. FIGS. 7C and 7D are cross-sectional views of the semiconductor structure 100B along lines C-C′ and D-D′ of FIG. 2B, respectively.

The dielectric interposers 144 may be used to replace the semiconductor layers 106A in the semiconductor structure 100A. As a result, the semiconductor layers 108A and the dielectric interposers 144 are stacked in an alternating manner. The dielectric interposers 144 may be made of a dielectric material, such as the dielectric material with a dielectric constant in a range from about 4 to about 7. In some embodiments, the dielectric interposers 144 has a density in a range from about 2 g/cm³ to about 3 g/cm³. The dielectric interposers 144 with lower k-value and lower density in the mentioned region can provide higher removal-efficiency or precise control during chemical etching or wet etching process due to its composition of Si, O, C, N.

In some embodiments, the dielectric interposers 144 are made of SiO₂, SiOCN, Si₃N₄, or another applicable materials. In some embodiments, the dielectric interposers 144 is formed by forming a dielectric material layer into the source/drain trenches 140A and the cavities 142 through a deposition process, such as CVD, PVD, ALD, HDPCVD, MOCVD, RPCVD, PECVD, LPCVD, ALCVD, APCVD, FCVD, other suitable methods, or combinations thereof. The dielectric material layer partially (or completely) fills the source/drain trenches 140A and fully fills the cavities 142.

In some embodiments, an etching process is then performed to selectively etch the dielectric material layer to form the dielectric interposers 144 with minimal etching (or substantially no etching) of the hard mask 110A, the semiconductor layers 108A, the substrate 102, the dummy gate structures 120, and the gate spacers 132A. The etching process may be an anisotropic etching process, such that portions of the dielectric material layer that do not vertically overlap or be covered by the dummy gate structures 120 and the gate spacers 132A are removed. In some embodiments, during the formation of the dielectric interposers 144, the semiconductor structure 100B may remain covered by the patterned mask 134, which allows semiconductor structure 100B to remain intact.

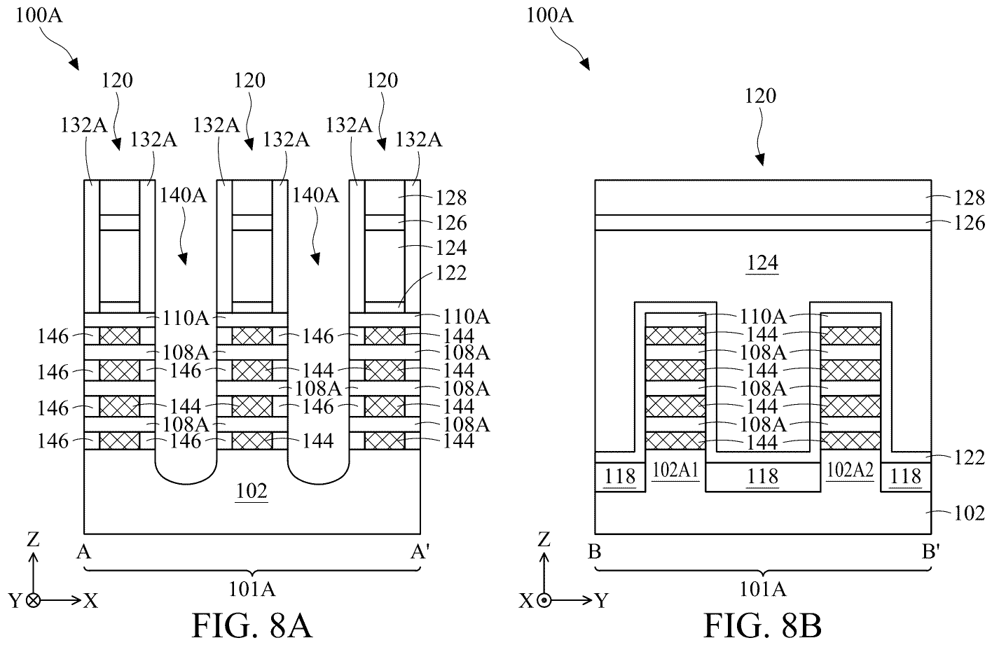

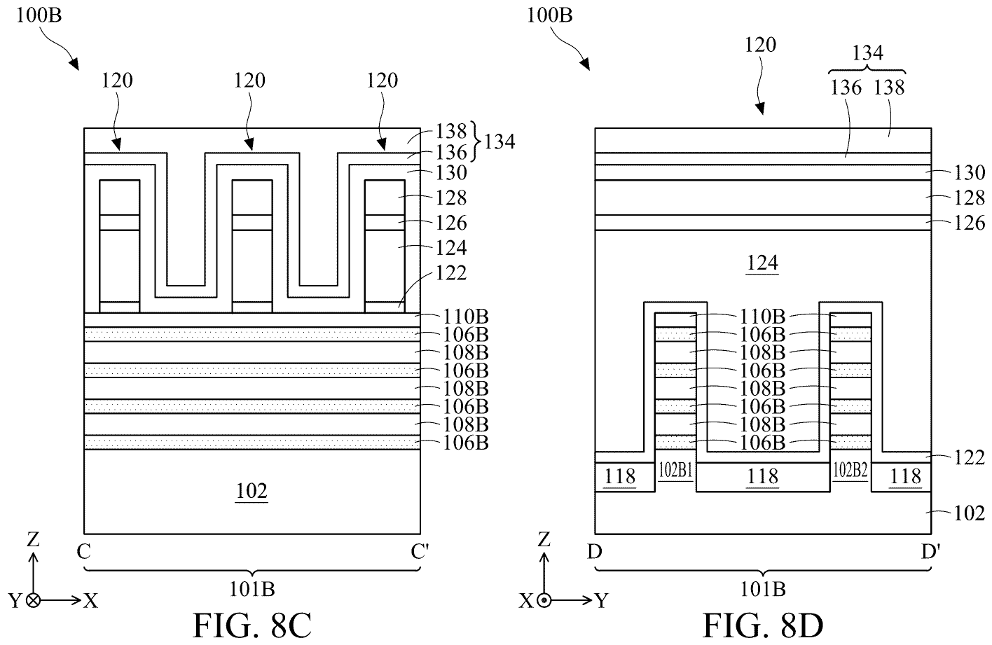

Referring to FIGS. 8A to 8D, the inner spacers 146 are formed between the semiconductor layers 108A and the hard masks 110A, between the semiconductor layers 108A, and between the semiconductor layers 108 and the substrate 102, in accordance with some embodiments. FIGS. 8A and 8B are cross-sectional views of the semiconductor structure 100A along lines A-A′ and B-B′ of FIG. 2A, respectively. FIGS. 8C and 8D are cross-sectional views of the semiconductor structure 100B along lines C-C′ and D-D′ of FIG. 2B, respectively.

In some embodiments, the dielectric interposers 144 exposed in the source/drain trenches 140A are partially recessed through a selective etching process, and the semiconductor layers 108A are not etched. More specifically, the selective etching process is performed that selectively etches the side portions of the dielectric interposers 144 below the gate spacers 132A through the source/drain trenches 140A, with minimal etching (or substantially no etching) of the semiconductor layers 108A and the substrate 102. After the selective etching process, inner spacer recesses are vertically formed between the hard mask 110A and the semiconductor layers 108A, between the semiconductor layers 108A, between the semiconductor layers 108A and the substrate 102, and below the gate spacers 132A. The selective etching process may be a dry etching process, a wet etching process, other suitable etching process, or a combination thereof.

Next, in some embodiments, a spacer layer is conformally formed into the source/drain trenches 140A and the inner spacer recesses by a deposition process, such as CVD, PVD, ALD, HDPCVD, MOCVD, RPCVD, PECVD, LPCVD, ALCVD, APCVD, FCVD, other suitable methods, or combinations thereof. The spacer layer partially (or completely) fills the source/drain trenches 140A and fully fills the inner spacer recesses. The deposition process is configured to ensure that the spacer layer fills the inner spacer recesses. Furthermore, the spacer layer is also conformally formed on the gate spacers 132A and the isolation structure 118.

The spacer layer may include a material that is different than the materials of the hard masks 110A, the semiconductor layers 108A, and the gate spacers 132A to achieve desired etching selectivity during the etching process. In some embodiments, the spacer layer include a dielectric material that includes Si, O, C, N, other suitable material, or combinations thereof (e.g., SiO₂, SION, SiOC, SiCN, SiOCN). In some embodiments, the spacer layer include a low-k dielectric material, such as those described herein. In some embodiments, the spacer layer includes a dielectric material having higher or lower k value (dielectric constant) than the gate spacers 132A.

Then, in some embodiments, the inner spacers 146 are formed to fill the inner spacer recesses between the hard masks 110A and the semiconductor layers 108A, between the semiconductor layers 108A, and between the semiconductor layers 108A and the substrate 102. Specifically, an etching process is performed to selectively etch the spacer layer to form the inner spacers 146 with minimal etching (or substantially no etching) of the hard mask 110A, the semiconductor layers 108A, the substrate 102, the dummy gate structures 120, and the gate spacers 132A. The etching process may be an anisotropic etching process, so that portions of the spacer layer that do not vertically overlap or be covered by the dummy gate structures 120 and the gate spacers 132A are removed. The spacer layer on the gate spacers 132A and the isolation structures 118 are also removed. In some embodiments, during the formation of the inner spacers 146, the semiconductor structure 100B may remain covered by the patterned mask 134, which allows semiconductor structure 100B to remain intact.

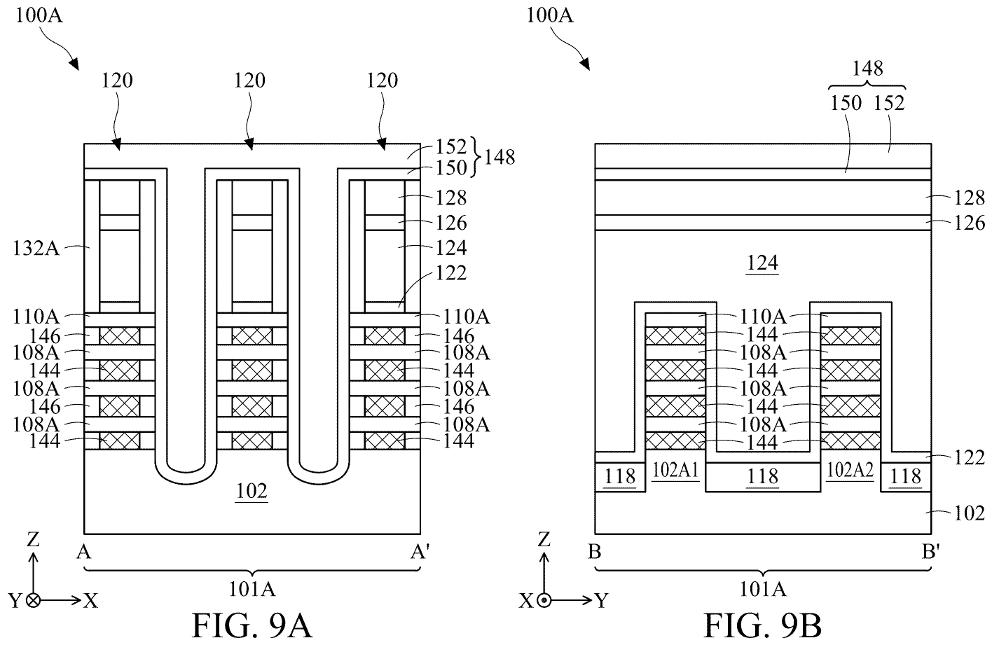

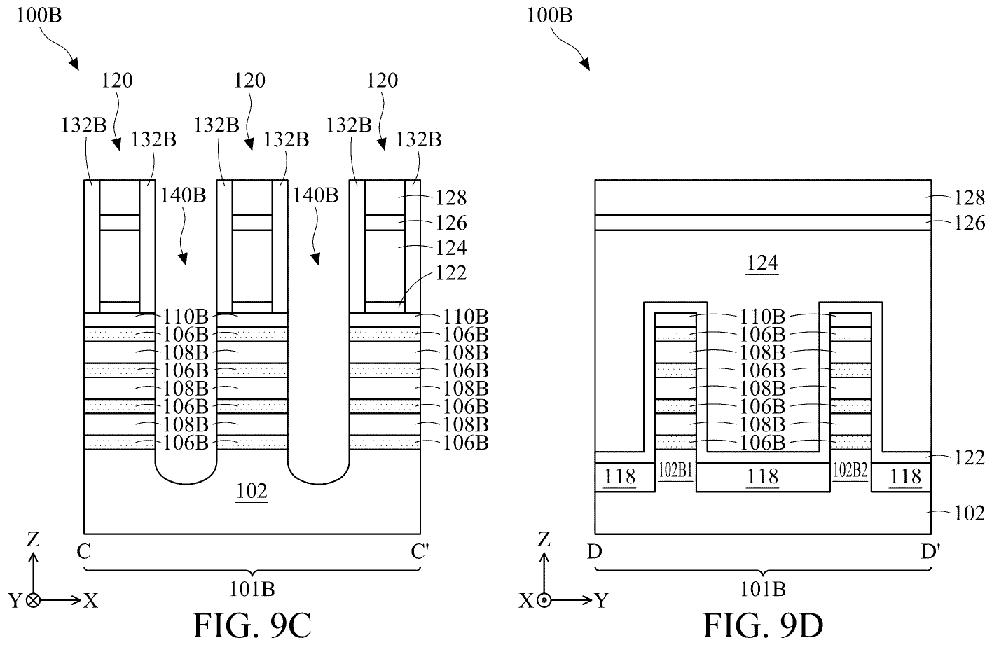

Referring to FIGS. 9A to 9D, the patterned mask 134 is removed from the semiconductor structure 100B, and a patterned mask 148 is formed to cover semiconductor structure 100A while remaining the semiconductor structure 100B exposed, in accordance with some embodiments. FIGS. 9A and 9B are cross-sectional views of the semiconductor structure 100A along lines A-A′ and B-B′ of FIG. 2A, respectively. FIGS. 9C and 9D are cross-sectional views of the semiconductor structure 100B along lines C-C′ and D-D′ of FIG. 2B, respectively.

In some embodiments, the patterned mask 134 is removed to expose the semiconductor structure 100B. For example, the patterned mask 134 may be removed by stripping process, ashing process, and/or etching process. Then, in some embodiments, the patterned mask 148 is formed to cover semiconductor structure 100A while remaining the semiconductor structure 100B exposed. The patterned mask 148 may be formed to have a sufficiently great thickness (or height) such that the top surface and sidewalls of the semiconductor structure 100A are fully covered, as shown in FIGS. 9A and 9B. Formation of the patterned mask 148 may allow one or more processes to be performed on the semiconductor structure 100B only. The patterned mask 148 may include a first mask 150 and a second mask 152 over the first mask 150, as shown in FIGS. 9A and 9B. In some embodiments, the first mask 150 includes nitride, and the second mask 152 includes photoresist.

Still referring to FIGS. 9A to 9D, gate spacers 132B are formed on sidewalls of the dummy gate structures 120 of the semiconductor structure 100B, and over the top surfaces and on the sidewalls of the fin structures 116B1 and 116B2, in accordance with some embodiments. In some embodiments, an anisotropic etching process is performed to remove horizontal portions of the spacer layer 130 from the top surfaces of the fin structures 116B1 and 116B2 and the dummy gate structures 120 in the region 101B. After the anisotropic etching process, in the region 101B, the portions of the spacer layer 130 on sidewall surfaces of the fin structures 116B1 and 116B2 and the dummy gate structures 120 substantially remain and become the gate spacers 132B. In some embodiments, the anisotropic etching process is a dry (e.g., plasma) etching process.

Still referring to FIGS. 9A to 9D, the fin structures 116B1 and 116B2 are recessed to form source/drain trenches in the fin structures 116B1 and 116B2 (or passing through semiconductor layers 106B and 108B and the hard mask 110B) for source/drain regions of the semiconductor structure 100B, in accordance with some embodiments. In some embodiments, in the semiconductor structure 100B, the source/drain trenches 140B are formed on opposite sides of the dummy gate structures 120 in the X-direction. Specifically, the source/drain trenches 140B may be formed by performing one or more etching processes to remove portions of the hard mask 110B, the semiconductor layers 106B and 108B, and the substrate 102 (e.g., base fins 102B1 and 102B2) that do not vertically overlap or not be covered by the dummy gate structures 120 and the gate spacers 132B.

In some embodiments, a single etchant may be used to remove the hard mask 110B, the semiconductor layers 106B and 108B, and the substrate 102. In other embodiments, multiple etchants may be used to perform the etching process. In some embodiments, portions of the substrate 102 are etched, so that the source/drain trenches 140B extend into the substrate and each has a concave surface in the substrate 102, as shown in FIG. 9C. In some embodiments, portions of the gate spacers 132B on opposite sidewalls of the fin structures 116B1 and 116B2 in the Y-direction are removed. In these embodiments, the height of the gate spacers 132B on opposite sidewalls of the fin structures 116B1 and 116B2 in the Y-direction are reduced (see FIG. 19F below).

In some embodiments, the formation of the gate spacers 132B and the formation of the source/drain trenches 140B are performed in the same etching process. In some embodiments, during the formation of the gate spacers 132B and the formation of the source/drain trenches 140B, the semiconductor structure 100A may remain covered by the patterned mask 148, which allows semiconductor structure 100A to remain intact.

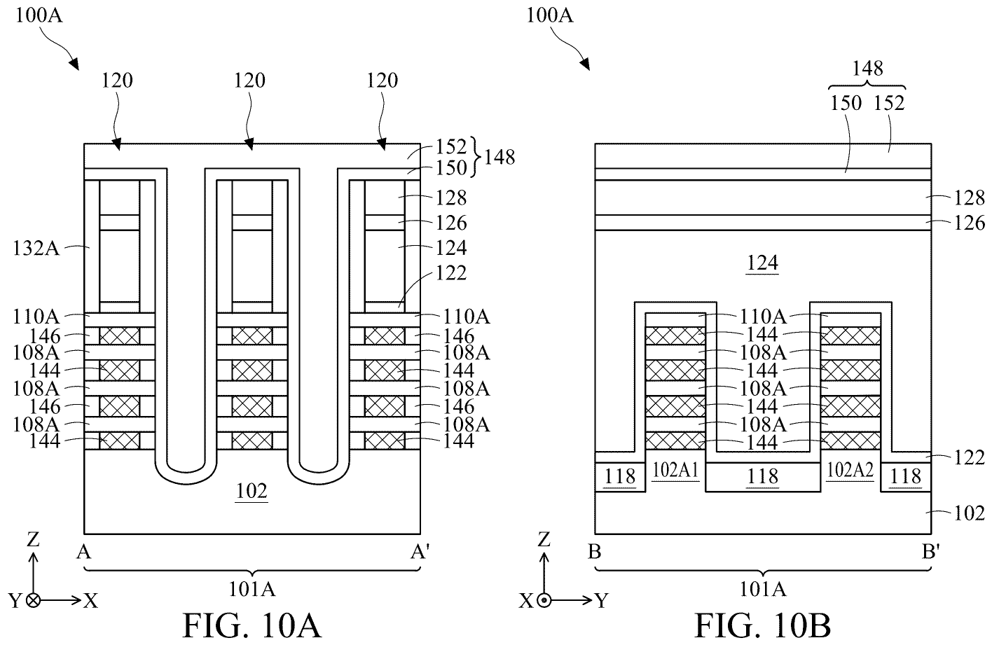

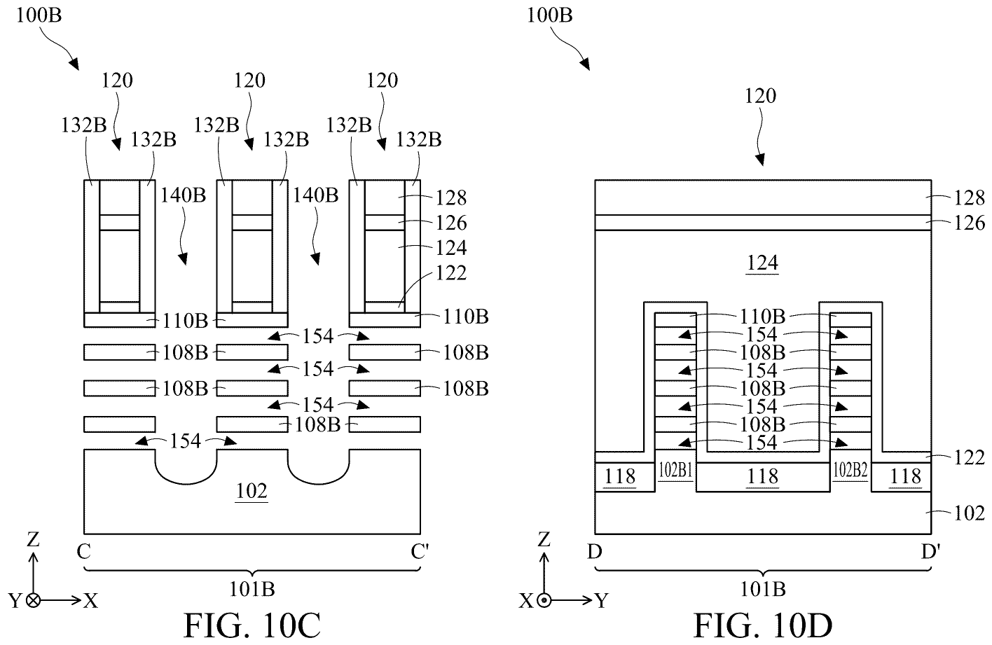

Referring to FIGS. 10A to 10D, the semiconductor layers 106B are removed through the source/drain trenches 140B to form cavities 154, in accordance with some embodiments. FIGS. 10A and 10B are cross-sectional views of the semiconductor structure 100A along lines A-A′ and B-B′ of FIG. 2A, respectively. FIGS. 10C and 10D are cross-sectional views of the semiconductor structure 100B along lines C-C′ and D-D′ of FIG. 2B, respectively.

In some embodiments, in the region 101B, the semiconductor layers 106B exposed in the source/drain trenches 140B are removed through a selective etching process, and the semiconductor layers 108B are not etched. More specifically, the selective etching process is performed that selectively etches the semiconductor layers 106B through the source/drain trenches 140B, with minimal etching (or substantially no etching) of the hard mask 110B, the semiconductor layers 108B, and the substrate 102. After the selective etching process, the cavities 154 are vertically formed between the hard masks 110B and the semiconductor layers 108B, between the semiconductor layers 108B, between the semiconductor layers 108B and the substrate 102, and below the dummy gate structures 120 and the gate spacers 132B. The selective etching process may be a dry etching process, a wet etching process, other suitable etching process, or a combination thereof. In some embodiments, all of the semiconductor layers 106B are removed. In some embodiments, during the removal of the semiconductor layers 106B and the formation of the cavities 154, the semiconductor structure 100A may remain covered by the patterned mask 148, which allows semiconductor structure 100A to remain intact.

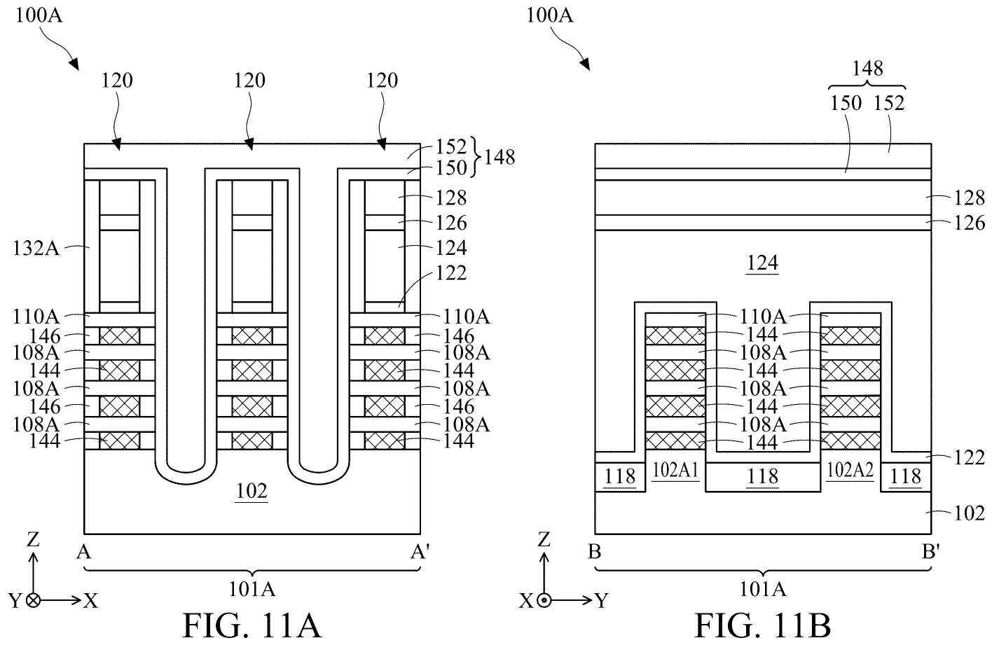

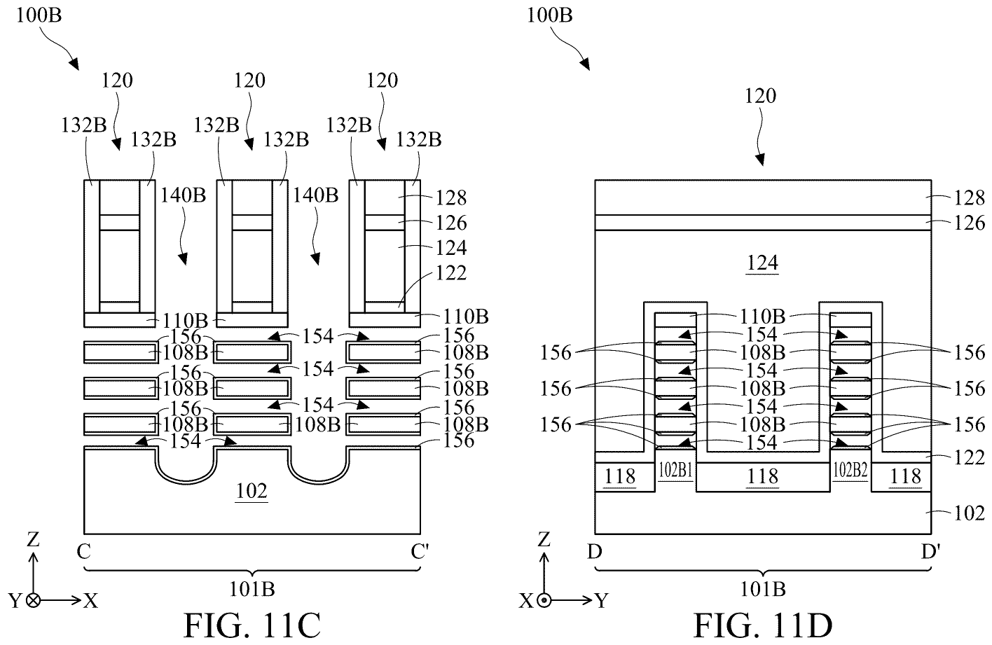

Referring to FIGS. 11A to 11D, an epitaxial growth process is performed to form epitaxial layers 156 on surfaces of the semiconductor layers 108B and the substrate 102 exposed in the cavities 154 and the source/drain trenches 140B, in accordance with some embodiments. FIGS. 11A and 11B are cross-sectional views of the semiconductor structure 100A along lines A-A′ and B-B′ of FIG. 2A, respectively. FIGS. 11C and 11D are cross-sectional views of the semiconductor structure 100B along lines C-C′ and D-D′ of FIG. 2B, respectively.

In some embodiments, the epitaxial layers 156 are epitaxially grown on the surfaces of the semiconductor layers 108B and the substrate 102 exposed in cavities 154 and the source/drain trenches 140B by an epitaxial growth process. The epitaxial growth process may be VPE, MOCVD, MBE, although other deposition processes, such as CVD, LPCVD, PECVD, ALD, HVCVD, RPCVD, a combination thereof, or the like, may also be utilized. In some embodiments, the epitaxial layers 156 include the same material as the semiconductor layers 108B. For example, when the semiconductor layers 108B include silicon, the epitaxial layers 156 may also include silicon. In some embodiments, the epitaxial layers 156 are wrapped around each of the semiconductor layers 108B in the X-Z plane, and on the top surfaces of the substrate 102 (e.g., on the top surfaces of the base fins 102B1 and 102B2 and on the bottoms of the source/drain trenches 140B), as shown in FIGS. 11C and 11D. In some embodiments, during the formation of the epitaxial layers 156, the semiconductor structure 100A may remain covered by the patterned mask 148, which allows semiconductor structure 100A to remain intact.

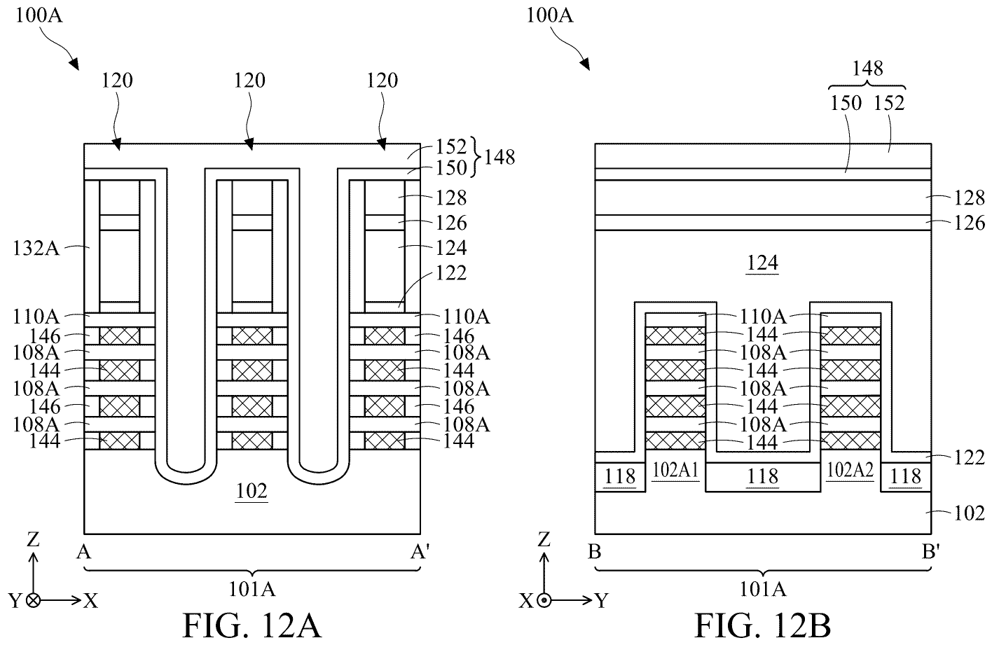

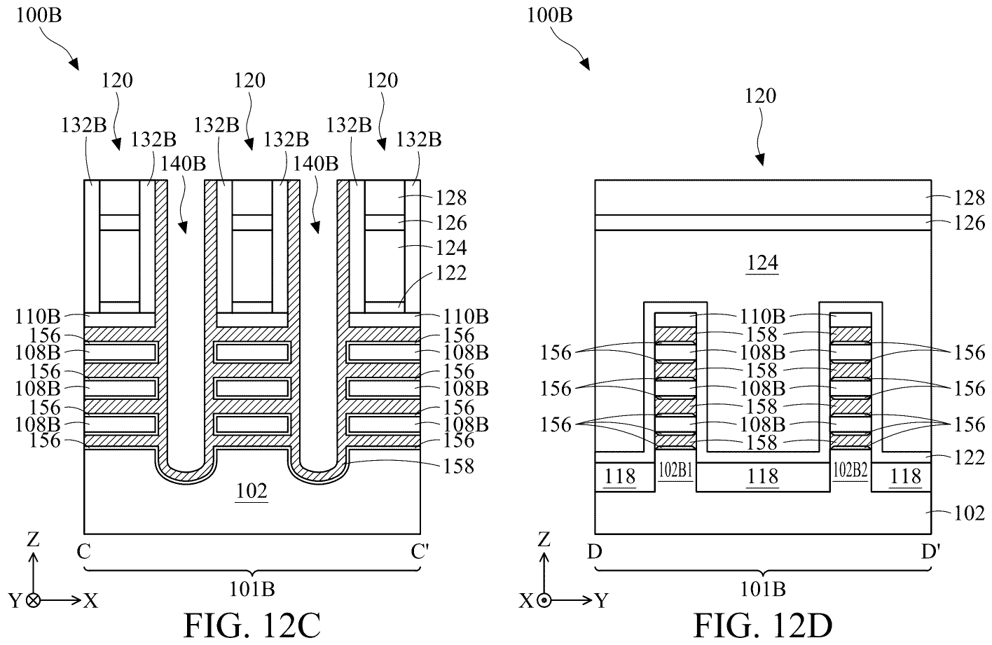

Referring to FIGS. 12A to 12D, a dielectric material layer 158 is conformally formed into the source/drain trenches 140B and the remaining portions of the cavities 154, in accordance with some embodiments. FIGS. 12A and 12B are cross-sectional views of the semiconductor structure 100A along lines A-A′ and B-B′ of FIG. 2A, respectively. FIGS. 12C and 12D are cross-sectional views of the semiconductor structure 100B along lines C-C′ and D-D′ of FIG. 2B, respectively.

In some embodiments, a deposition process is performed to form the dielectric material layer 158 into the source/drain trenches 140B and the cavities 154, such as CVD, PVD, ALD, HDPCVD, MOCVD, RPCVD, PECVD, LPCVD, ALCVD, APCVD, FCVD, other suitable methods, or combinations thereof. The dielectric material layer 158 partially (or completely) fills the source/drain trenches 140B and fully fills the remaining portions of the cavities 154, as shown in FIG. 12C. The deposition process is configured to ensure that the dielectric material layer 158 fills the remaining portions of the cavities 154 between the hard masks 110B and the semiconductor layers 108B, between the semiconductor layers 108B, and between the semiconductor layers 108B and the substrate 102. More specifically, the dielectric material layer 158 fills the remaining portions of the cavities 154 between the hard masks 110B and the epitaxial layers 156 formed on the semiconductor layers 108B, between the epitaxial layers 156 formed on the semiconductor layers 108B, and between the epitaxial layers 156 formed on the semiconductor layers 108B and the epitaxial layer 156 formed on the substrate 102. In some embodiments, the dielectric material layer 158 includes a dielectric material that includes silicon, oxygen, carbon, nitrogen, other suitable material, or combinations thereof (e.g., SiN, SiCN, SiOCN). In some embodiments, during the formation of the dielectric material layer 158, the semiconductor structure 100A may remain covered by the patterned mask 148, which allows semiconductor structure 100A to remain intact.

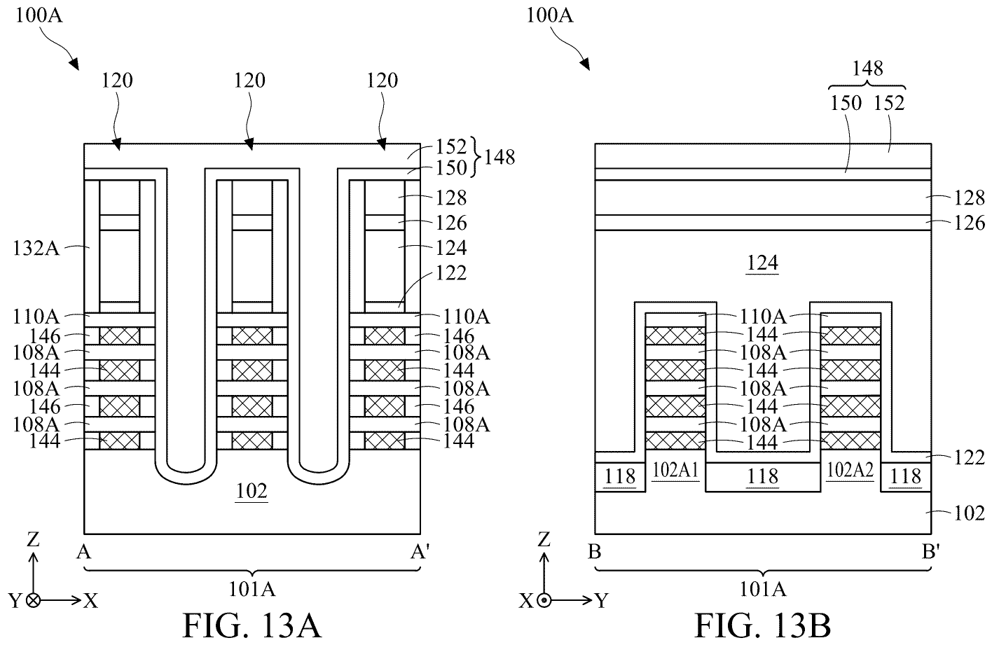

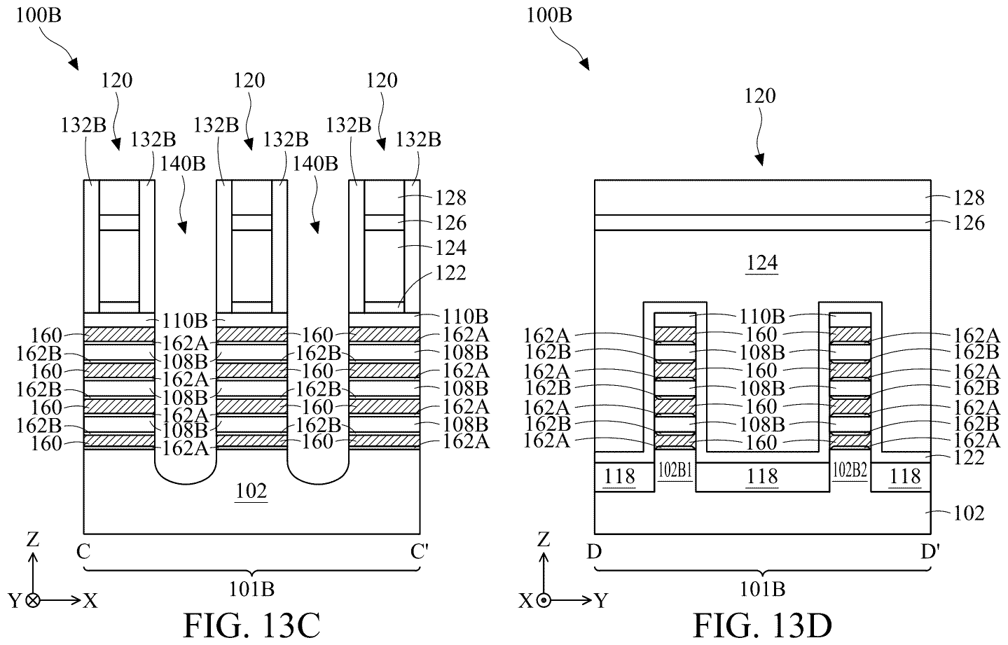

Referring to FIGS. 13A to 13D, dielectric layers 160 are formed to fill the cavities 154 between the hard masks 110B and the semiconductor layers 108B, between the semiconductor layers 108B, and between the semiconductor layers 108B and the substrate 102, in accordance with some embodiments. FIGS. 13A and 13B are cross-sectional views of the semiconductor structure 100A along lines A-A′ and B-B′ of FIG. 2A, respectively. FIGS. 13C and 13D are cross-sectional views of the semiconductor structure 100B along lines C-C′ and D-D′ of FIG. 2B, respectively.

In some embodiments, an etching process is performed to selectively etch the dielectric material layer 158 to form the dielectric layers 160 in the cavities 154. The etching process may be an anisotropic etching process, such that portions of the dielectric material layer 158 that are exposed in the source/drain trenches 140B (i.e., that do not vertically overlap or be covered by the dummy gate structure 120 and the gate spacers 132B) are removed. In some embodiments, the portions of the epitaxial layers 156 that are exposed in the source/drain trenches 140B (i.e., that do not vertically overlap or be covered by the dummy gate structure 120 and the gate spacers 132B) are also removed by the etching process.

After the etching process, the dielectric layers 160 may be formed between the hard masks 110B and the semiconductor layers 108B, between the semiconductor layers 108B, and between the semiconductor layers 108B and the substrate 102, as shown in FIGS. 13C and 13D. Furthermore, after the etching process, the epitaxial layers 156 are partially removed, and the remaining portions of the epitaxial layers 156 include upper epitaxial layers 162A and lower epitaxial layers 162B (may be collectively referred to as epitaxial layers 162). In some embodiments, the upper epitaxial layers 162A are formed on the upper surfaces of the semiconductor layers 108B, and the lower epitaxial layers 162B are formed on the lower surfaces of the semiconductor layers 108B, as shown in FIGS. 13C and 13D. In further embodiments, the upper epitaxial layers 162A are also formed on surfaces of the substrate 102 that vertically overlap the semiconductor layers 108B, as shown in FIGS. 13C and 13D.

In some embodiments, the dielectric layers 160 are formed between the hard masks 110B and the upper epitaxial layers 162A formed on the semiconductor layers 108B, between the upper epitaxial layers 162A and the lower epitaxial layers 162B formed on the semiconductor layers 108B, and between the lower epitaxial layers 162B formed on the semiconductor layers 108B and the upper epitaxial layers 162A formed on the substrate 102. In some embodiments, during the formation of the dielectric layers 160 and the formation of the epitaxial layers 162, the semiconductor structure 100A may remain covered by the patterned mask 148, which allows semiconductor structure 100A to remain intact.

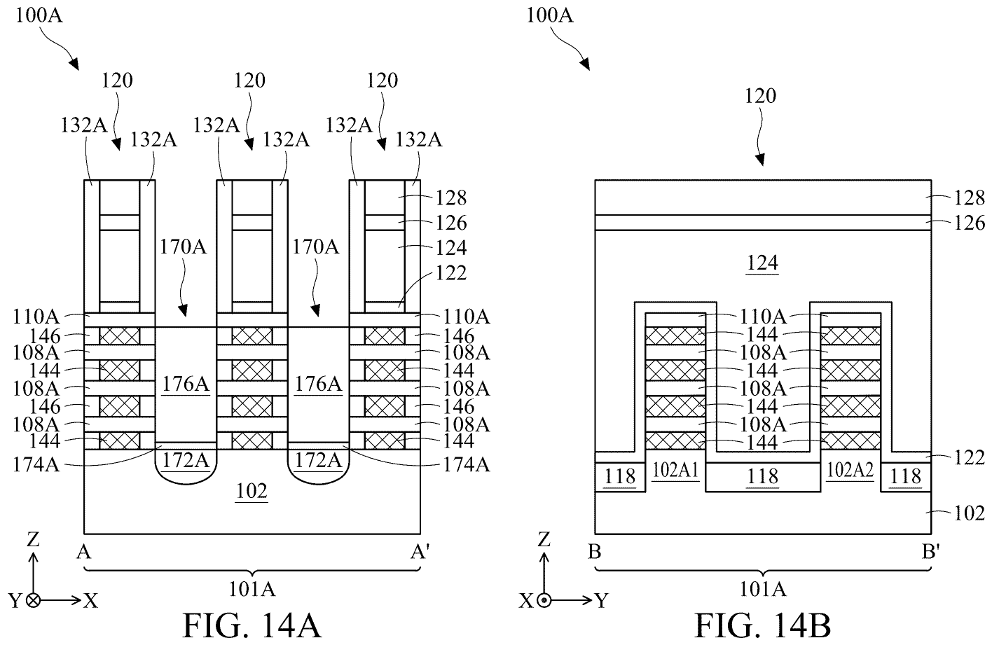

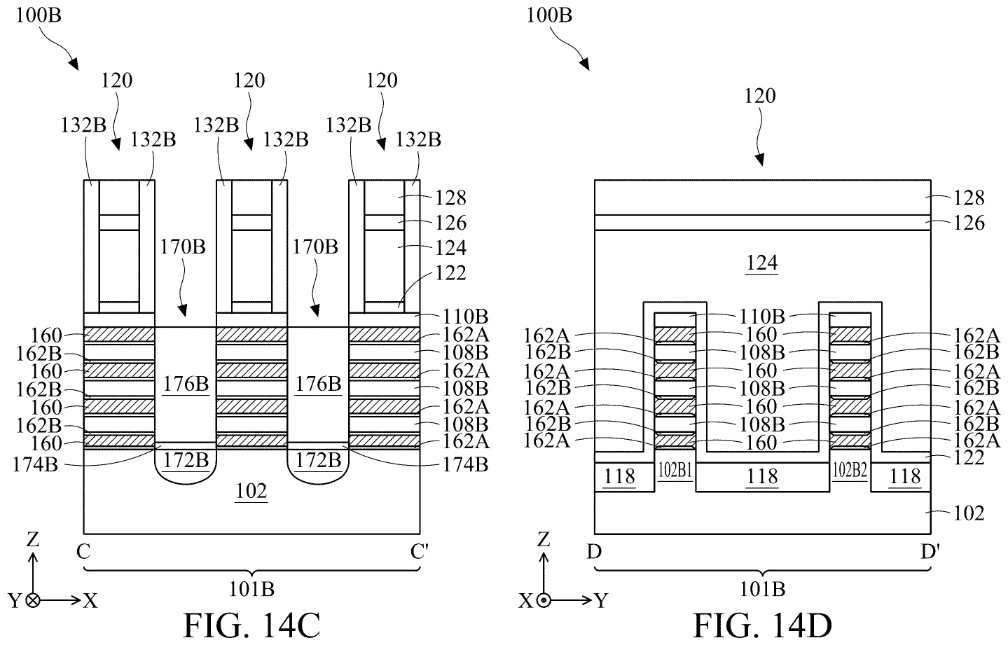

Referring to FIGS. 14A to 14D, the patterned mask 148 is removed from the semiconductor structure 100A, and the source/drain features are formed in both the semiconductor structures 100A and 100B, in accordance with some embodiments. FIGS. 14A and 14B are cross-sectional views of the semiconductor structure 100A along lines A-A′ and B-B′ of FIG. 2A, respectively. FIGS. 14C and 14D are cross-sectional views of the semiconductor structure 100B along lines C-C′ and D-D′ of FIG. 2B, respectively. In some embodiments, the patterned mask 148 is removed to expose the semiconductor structure 100A. For example, the patterned mask 148 may be removed by stripping process, ashing process, and/or etching process.

Still referring to FIGS. 14A to 14D, the source/drain features 170A are formed in the source/drain trenches 140A in the region 101A, and the source/drain features 170B are formed in the source/drain trenches 140B in the region 101B, in accordance with some embodiments. In some embodiments, each of the source/drain features 170A includes a first epitaxial layer 172A, a bottom isolation layer 174A over the first epitaxial layer 172A, and a second epitaxial layer 176A over the bottom isolation layer 174A. Similarly, each of the source/drain features 170B includes a first epitaxial layer 172B, a bottom isolation layer 174B over the first epitaxial layer 172B, and a second epitaxial layer 176B over the bottom isolation layer 174B. The source/drain features 170A and 170B may also be referred to as source/drain, or source/drain regions. In some embodiments, the source/drain feature(s) 170A and 170B may refer to a source or a drain, individually or collectively dependent upon the context.

In some embodiments, the first epitaxial layers 172A and 172B are formed on bottoms of the source/drain trenches 140A and 140B, respectively, such that the first epitaxial layers 172A and 172B extend into are in direct contact with the substrate 102 in the Z-direction. In some embodiments, the first epitaxial layers 172A and 172B are substantially free of dopants. The first epitaxial layers 172A and 172B may include Si, Ge, SiGe, other suitable semiconductor materials, or combinations thereof. In some embodiments, the first epitaxial layers 172A and 172B include silicon that is substantially free of n-type dopants and p-type dopants. In some embodiments, the first epitaxial layers 172A and 172B are epitaxially grown using an epitaxial growth process such as VPE, MOCVD, MBE, although other deposition processes, such as CVD, LPCVD, PECVD, ALD, UHVCVD, RPCVD, combinations thereof, or the like, may also be utilized.

In some embodiments, the bottom isolation layers 174A and 174B are formed on the first epitaxial layers 172A and 172B, respectively. In some embodiments, the bottom isolation layers 174A and 174B may be a single dielectric layer or a multiple dielectric layers structure. In some embodiments, the dielectric material of the bottom isolation layers 174A and 174B may include Si₃N₄, SiO₂, SiC, SiOC, SiON, SiCN, SiOCN, high-k dielectrics, other suitable materials, or combinations thereof. In some embodiments, the bottom isolation layers 174A and 174B may be deposited by CVD, PVD, ALD, HDPCVD, MOCVD, RPCVD, PECVD, LPCVD, ALCVD, APCVD, other suitable methods, or combinations thereof.

In some embodiments, the second epitaxial layers 176A and 176B are formed over the bottom isolation layers 174A and 174B, respectively. In some embodiments, the second epitaxial layers 176A and 176B may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. In some embodiments, the second epitaxial layers 176A and 176B are grown from the semiconductor layers 108A and 108B, respectively.

In some embodiments, the source/drain features 170A and 170B are used for p-type FETs (PFETs) or n-type FETs (NFETs), and thus may be referred to as p-type or n-type source/drain features, respectively. For the p-type source/drain features, the second epitaxial layers 176A and 176B may include epitaxially-grown material selected from a group consisting of boron-doped SiGe, boron-doped SiGeC, boron-doped Ge, boron-doped Si, boron and carbon doped SiGe, or a combination thereof. In some embodiments, the second epitaxial layers 176A and 176B of the p-type source/drain features may be doped with p-type dopants and have a doping concentration in a range from about 1×10¹⁹/cm³ to 6×10²⁰/cm³.

For the n-type source/drain features, the second epitaxial layers 176A and 176B may include epitaxially-grown material selected from a group consisting of SiP, SiC, SiPC, SiAs, Si, or a combination thereof. In some embodiments, the second epitaxial layers 176A and 176B of the n-type source/drain features may be doped with n-type dopants and have a doping concentration in a range from about 2×10¹⁹/cm³ to 3×10²¹/cm³. The second epitaxial layers 176A and 176B may be doped in-situ or ex-situ. One or more annealing processes may be performed to activate the dopants in the second epitaxial layers 176A and 176B. The annealing processes may include rapid thermal annealing (RTA) and/or laser annealing processes.

In some embodiments, in the semiconductor structure 100A, the source/drain features 170A are formed on the opposite sides of the dummy gate structures 120 in the X-direction, and are connected to and in contact with the semiconductor layers 108A. That is, the second epitaxial layers 176A are attached to the opposite sides of the semiconductor layers 108A. In some embodiments, in the Z-direction, the second epitaxial layers 176A may have top surfaces that extend higher than the top surfaces of the topmost semiconductor layers 108A. The top surfaces of the second epitaxial layers 176A may be higher, level with, or lower than the bottom surfaces of the hard masks 110A.

In some embodiments, the top surfaces of the bottom isolation layers 174A are lower than the bottommost semiconductor layers 108A. In some embodiments, the bottom surfaces of the bottom isolation layers 174A and the top surfaces of the first epitaxial layers 172A are level with the topmost surface of the substrate 102. In other embodiments, the bottom surfaces of the bottom isolation layers 174A and the top surfaces of the first epitaxial layers 172A are higher than the topmost surface of the substrate 102.

In some embodiments, in the semiconductor structure 100B, the source/drain features 170B are formed on the opposite sides of the dummy gate structures 120 in the X-direction, and are connected to and in contact with the semiconductor layers 108B (including the epitaxial layers 162). That is, the second epitaxial layers 176B are attached to the opposite sides of the semiconductor layers 108B (including the epitaxial layers 162). In some embodiments, the second epitaxial layers 176B may have top surfaces that extend higher than the top surfaces of the upper epitaxial layers 162A formed on the topmost semiconductor layers 108B in the Z-direction. The top surfaces of the second epitaxial layers 176B may be higher, level with, or lower than the bottom surfaces of the hard masks 110B.

In some embodiments, the top surfaces of the bottom isolation layers 174B are lower than the lower epitaxial layers 162B formed on the lower surfaces of the bottommost semiconductor layers 108B. In some embodiments, the interfaces between the bottom isolation layers 174B and the first epitaxial layers 172B are between the top surfaces and the bottom surfaces of the bottommost upper epitaxial layers 162A in the Z-direction, wherein the bottommost upper epitaxial layers 162A are formed on the surface of the substrate 102. In other embodiments, the interfaces between the bottom isolation layers 174B and the first epitaxial layers 172B are between the top surfaces and the bottom surfaces of the bottommost dielectric layers 160.

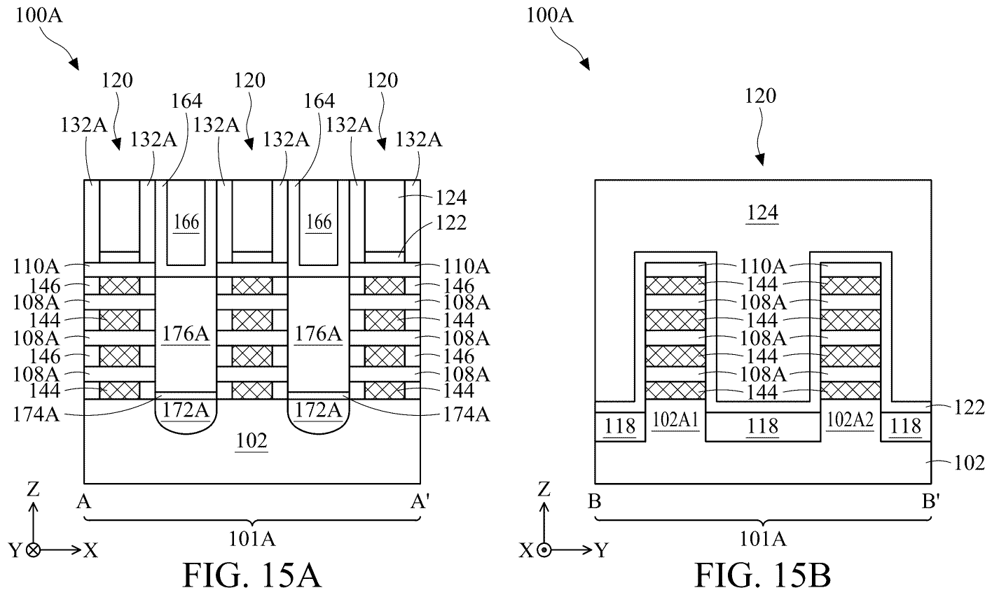

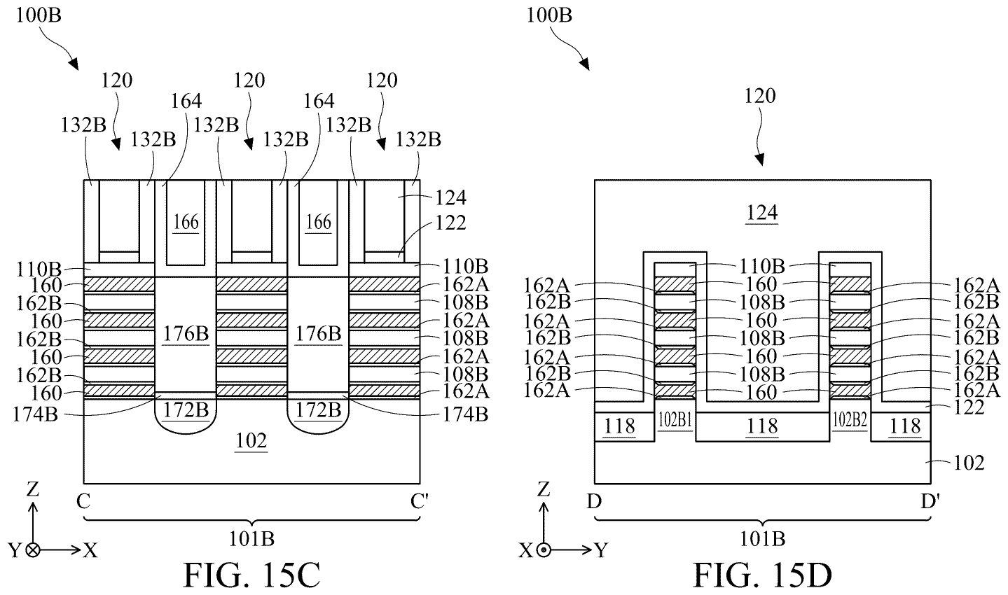

Referring to FIGS. 15A to 15D, contact etch stop layers (CESLs) 164 over the source/drain features 170A and 170B and interlayer dielectric (ILD) layers 166 over the CESLs 164 are formed to fill the spaces between the gate spacers 132A and between the gate spacers 132B, in accordance with some embodiments. FIGS. 15A and 15B are cross-sectional views of the semiconductor structure 100A along lines A-A′ and B-B′ of FIG. 2A, respectively. FIGS. 15C and 15D are cross-sectional views of the semiconductor structure 100B along lines C-C′ and D-D′ of FIG. 2B, respectively.

In some embodiments, the CESLs 164 are conformally formed on the sidewalls of the gate spacers 132A and 132B, and over the top surfaces of the source/drain features 170A and 170B, as shown in FIGS. 15A and 15C. The ILD layers 166 are formed over and between the CESLs 164 to fill the spaces between the CESLs 164 or between the gate spacers 132A or 132B.

The CESLs 164 may include a material that is different than ILD layers 166. The CESLs 164 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESLs 164 may be formed by CVD, PVD, ALD, HDPCVD, MOCVD, RPCVD, PECVD, LPCVD, ALCVD, APCVD, FCVD, or other suitable methods. The ILD layer 166 may include tetraethylorthosilicate (TEOS) formed oxide, un-doped silicate glass, or doped silicon oxide such as borophosphosilicate glass (BPSG), FSG, phosphosilicate glass (PSG), boron doped silicon glass (BSG), a low-k dielectric material, other suitable dielectric material, or combinations thereof. The ILD layers 166 may be formed by CVD, PVD, ALD, HDPCVD, MOCVD, RPCVD, PECVD, LPCVD, ALCVD, APCVD, FCVD, or other suitable methods.

Subsequent to the deposition of the CESLs 164 and the ILD layers 166, a CMP process and/or some other planarization process is performed on the CESLs 164, the ILD layers 166, the gate spacers 132A and 132B, and the hard masks 126 and 128 until the top surfaces of the dummy gate electrode layers 124 are exposed. In some embodiments, portions of the dummy gate electrode layers 124 are removed after the planarization process.

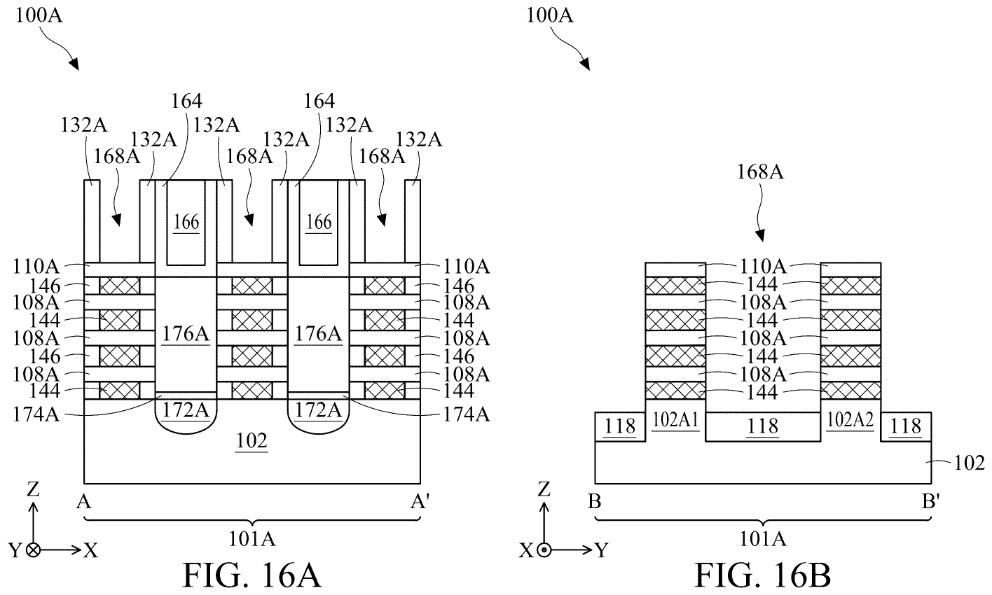

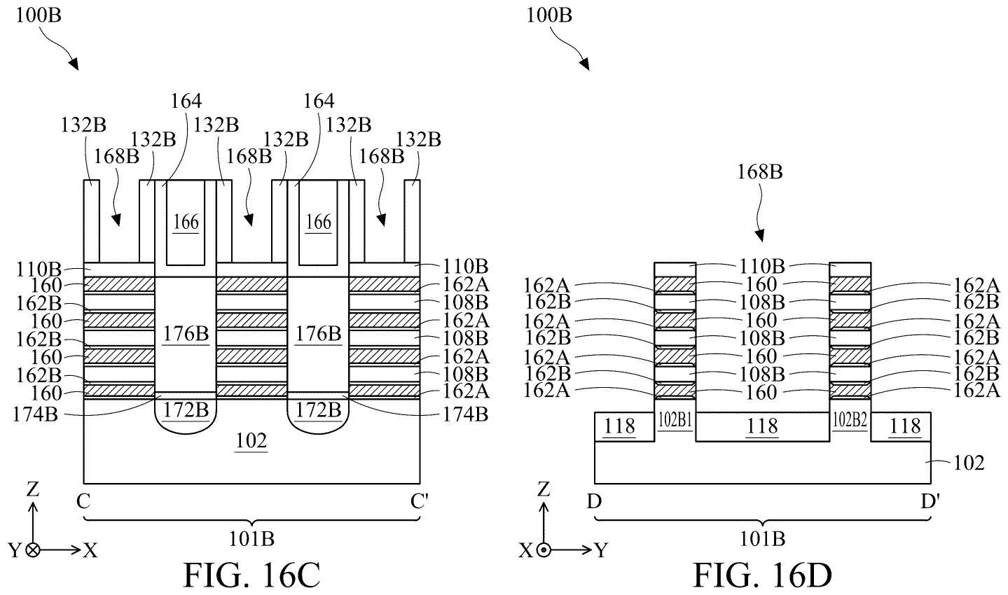

Referring to FIGS. 16A to 16D, the dummy gate structures 120 are selectively removed through any suitable photolithography and etching processes, in accordance with some embodiments. FIGS. 16A and 16B are cross-sectional views of the semiconductor structure 100A along lines A-A′ and B-B′ of FIG. 2A, respectively. FIGS. 16C and 16D are cross-sectional views of the semiconductor structure 100B along lines C-C′ and D-D′ of FIG. 2B, respectively.

In some embodiments, the photolithography process may include forming a photoresist layer, exposing the photoresist to a pattern, performing a post-exposure bake process, and developing the photoresist to form a masking element, which exposes a region including the dummy gate structures 120. Then, the dummy gate structures 120 are selectively etched through the masking element. The gate spacers 132A and 132B may be used as the masking element or a part thereof. Etch selectivity may be achieved by selecting appropriate etching chemicals, and the dummy gate structures 120 may be removed without substantially affecting the CESLs 164 and the ILD layers 166. The removal of the dummy gate structures 120 creates gate trenches 168A and 168B in the semiconductor structures 100A and 100B, respectively, as shown in FIGS. 16A to 16D.

In some embodiments, in the region 101A, the gate trenches 168A expose the top surfaces of the hard masks 110A that underlie the dummy gate structures 120, and expose the sidewalls of the hard masks 110A, the semiconductor layers 108A, and the dielectric interposers 144 that are previously covered by the dummy gate structures 120. In some embodiments, in the region 101B, the gate trenches 168B expose the top surfaces of the hard masks 110B that underlie the dummy gate structures 120, and expose the sidewalls of the hard masks 110B, the semiconductor layers 108B, and the dielectric layers 160 that are previously covered by the dummy gate structures 120.

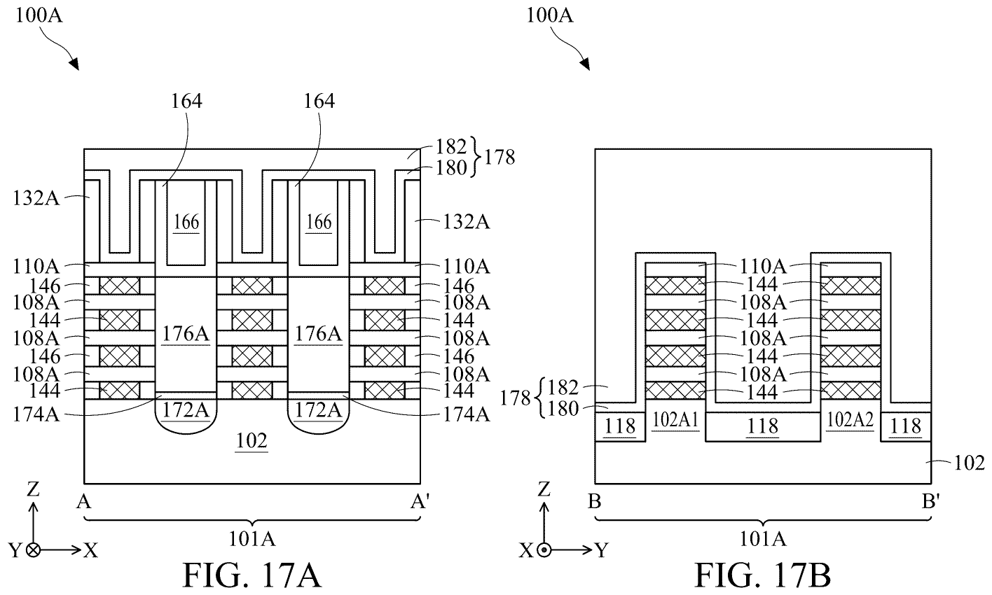

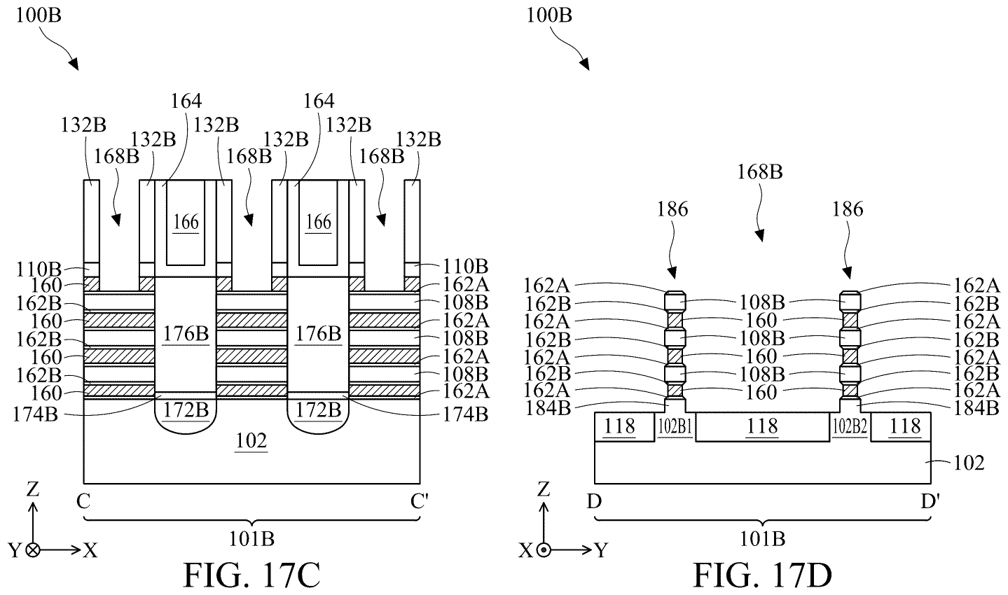

Referring to FIGS. 17A to 17D, a patterned mask 178 is formed to cover semiconductor structure 100A while remaining the semiconductor structure 100B exposed, in accordance with some embodiments. FIGS. 17A and 17B are cross-sectional views of the semiconductor structure 100A along lines A-A′ and B-B′ of FIG. 2A, respectively. FIGS. 17C and 17D are cross-sectional views of the semiconductor structure 100B along lines C-C′ and D-D′ of FIG. 2B, respectively.

In some embodiments, the patterned mask 178 may be formed to have a sufficiently great thickness (or height) such that the top surface and sidewalls of the semiconductor structure 100A are fully covered, as shown in FIGS. 17A and 17B. Formation of the patterned mask 178 may allow one or more processes to be performed on the semiconductor structure 100B only. The patterned mask 178 may include a first mask 180 and a second mask 182 over the first mask 180, as shown in FIGS. 17A and 17B. In some embodiments, the first mask 180 includes nitride, and the second mask 182 includes photoresist.

Still referring to FIGS. 17A to 17D, a trimming process is performed on the hard masks 110B, the dielectric layers 160, the semiconductor layers 108B, and the epitaxial layers 162, in accordance with some embodiments. In some embodiments, portions of the hard masks 110B exposed in the gate trenches 168B are first remove by a first etching process, so as to extend the gate trenches 168B and expose top surfaces of the topmost dielectric layers 160. The first etching process may include dry etching, wet etching, RIE, and/or other suitable processes.

Then, in some embodiments, the dielectric layers 160, the semiconductor layers 108B, and the epitaxial layers 162 are trimmed (i.e., partially removed) through the gate trenches 168B by a second etching process. The second etching process may include dry etching, wet etching, RIE, and/or other suitable processes. After the second etching process, in the Y-direction, the widths of portions of the dielectric layers 160, the semiconductor layers 108B, and the epitaxial layers 162 exposed in the gate trenches 168B are reduced, as shown in FIG. 17D. In some embodiments, portions of the base fins 102B1 and 102B2 protruding above the isolation structures 118 are also trimmed to have reduced width in the Y-direction, and may be referred to as base portions 184B.

Next, in some embodiments, the dielectric layers 160 are further trimmed (i.e., partially removed) through the gate trenches 168B by a third etching process. The third etching process may be a selective etching process that is performed to selectively etch the dielectric layers 160, with minimal etching (or substantially no etching) of the semiconductor layers 108B. The selective etching process may be a dry etching process, a wet etching process, other suitable etching process, or a combination thereof. After the third etching process, portions of the topmost dielectric layers 160 exposed in the gate trenches 168B may be removed, and the widths of portions of the remaining dielectric layers 160 exposed in the gate trenches 168B are further reduced in the Y-direction, so that in the gate trenches 168B, the widths of the semiconductor layers 108B are greater than the widths of the dielectric layers 160 in the Y-direction, as shown in FIG. 17D. In some embodiments, during the trimming process, the semiconductor structure 100A may remain covered by the patterned mask 178, which allows semiconductor structure 100A to remain intact.

After the trimming process, in the gate trenches 168B, stacks 186 are formed, wherein the stacks 186 are constituted by the dielectric layers 160, the semiconductor layers 108B, the epitaxial layers 162, and the base portions 184B that have been trimmed during the trimming process, as shown in FIGS. 17C and 17D. In some embodiments, in the stacks 186, the widths of the semiconductor layers 108B are the same as the widths of the base portions 184B, and smaller than the widths of the base fins 102B1 and 102B2 below the top surfaces of the isolation structures 118. In some embodiments, in the stacks 186, the widths of the semiconductor layers 108B are greater than the widths of the dielectric layers 160. In some embodiments, in the stacks 186, each of the dielectric layers 160 is in contact with one upper epitaxial layer 162A and one lower epitaxial layer 162B. In some embodiments, in the stacks 186, each of the upper epitaxial layer 162A and the lower epitaxial layer 162B has a trapezoidal shape in the Y-Z plane, as shown in FIG. 17D. In further embodiments, the trapezoidal shape has a long base and a short base, in the Y-direction, the long base has a width that is the same as the semiconductor layers 108B and the short base has a width that is the same as the dielectric layers 160.

In some embodiments, in the stacks 186, the dielectric layers 160 between the semiconductor layers 108B connect the semiconductor layers 108B to each other in a manner of connecting the lower epitaxial layer 162B formed on the lower surface of an upper semiconductor layer 108B to the upper epitaxial layer 162A formed on the upper surface of a lower semiconductor layer 108B. In some embodiments, in the stacks 186, the dielectric layers 160 connect the bottommost semiconductor layers 108B to the base portions 184B in a manner of connecting the lower epitaxial layer 162B formed on the lower surface of the bottommost semiconductor layer 108B to the upper epitaxial layer 162A formed on the upper surface of base portions 184B.

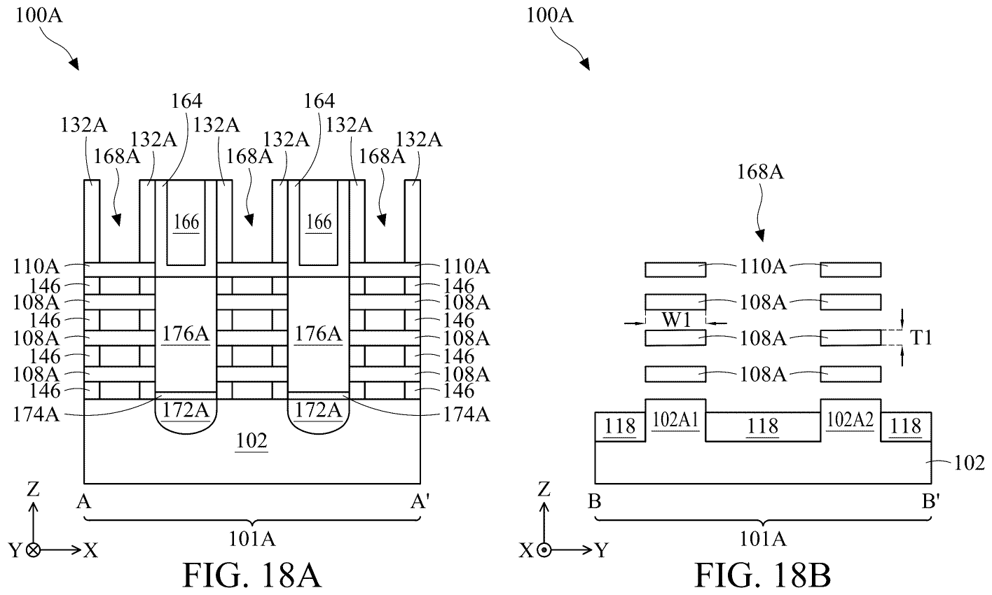

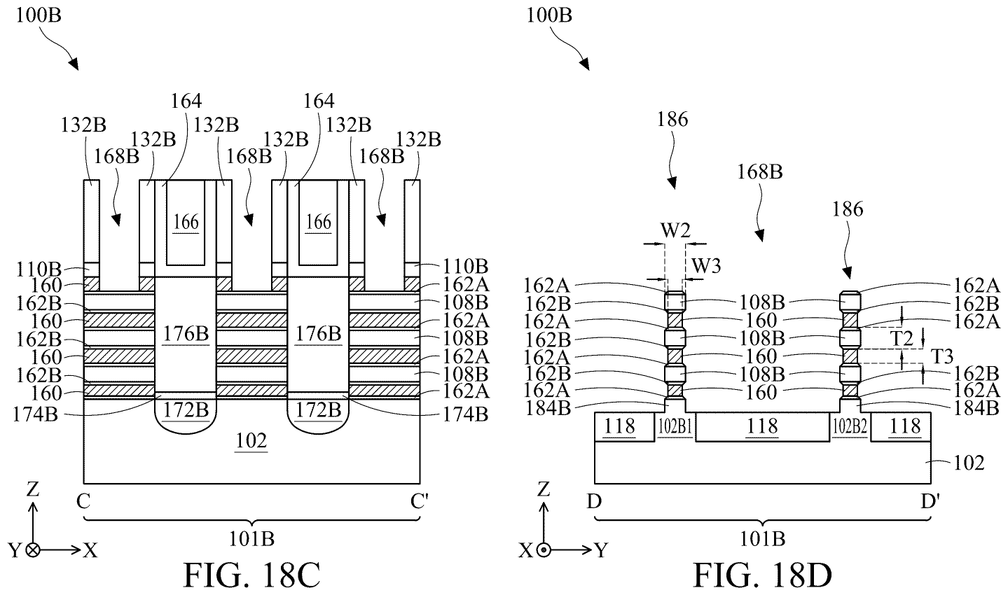

Referring to FIGS. 18A to 18D, the patterned mask 178 and the dielectric interposers 144 are removed from the semiconductor structure 100A, in accordance with some embodiments. FIGS. 18A and 18B are cross-sectional views of the semiconductor structure 100A along lines A-A′ and B-B′ of FIG. 2A, respectively. FIGS. 18C and 18D are cross-sectional views of the semiconductor structure 100B along lines C-C′ and D-D′ of FIG. 2B, respectively. In some embodiments, the patterned mask 178 is removed to expose the semiconductor structure 100A. For example, the patterned mask 178 may be removed by stripping process, ashing process, and/or etching process.

Still referring to FIGS. 18A to 18D, dielectric interposers 144 are selectively removed from the semiconductor structure 100A through the gate trenches 168A, using a wet or dry etching process for example, in accordance with some embodiments. After the dielectric interposers 144 are selectively removed, the gate trenches 168A are extended, and the semiconductor layers 108A are exposed in the gate trenches 168A to form the nanostructures stacked on top of each other. Similarly, in the semiconductor structure 100B, the semiconductor layers 108B exposed in the gate trenches 168B may also form the nanostructures stacked on top of each other. In some embodiments, the epitaxial layers 162 may also be considered parts of nanostructures. For example, in the semiconductor structure 100B, one nanostructure may include one semiconductor layers 108B in the middle, one upper epitaxial layer 162A extending upward as an upper protrusion, and one lower epitaxial layer 162B extending downward as a lower protrusion in the Z-direction.

In some embodiments, the semiconductor layers 108A are stacked over and spaced apart from each other, and suspended over and vertically arranged over the substrate 102 in the Z-direction, so as to constitute vertical stacks, as shown in FIGS. 18A and 18B. In some embodiments, the semiconductor layers 108B are stacked over and spaced apart from each other, and suspended over and vertically arranged over the substrate 102 in the Z-direction, so as to constitute stacks 186. In the stacks 186, the semiconductor layers 108B may be connected to each other and the base portions 184B through the dielectric layers 160, the upper epitaxial layer 162A, and the lower epitaxial layer 162B, as shown in FIGS. 17C, 17D, 18C, and 18D.

After the fabrication stage shown in FIGS. 18A to 18D, the semiconductor layers 108A may have a width W1 in the Y-direction and a thickness T1 in the Z-direction. In some embodiments, the width W1 is in a range from about 8 nm to about 13 nm, or greater than about 16 nm. In some embodiments, the thickness T1 is in a range from about 4 nm to about 6 nm. After the fabrication stage shown in FIGS. 18A to 18D, the semiconductor layers 108B may have a width W2 and the dielectric layers 160 may have a width W3 in the Y-direction. In some embodiments, the width W2 is in a range from about 4 nm to about 6 nm, and the width W3 is in a range from about 2 nm to about 3.5 nm. In some embodiments, a combination of one semiconductor layer 108B, one upper epitaxial layer 162A, and one lower epitaxial layer 162BA has a thickness T2 that is in a range from about 9 nm to about 11 nm in the Z-direction. In some embodiments, the dielectric layers 160 have a thickness T3 that is in a range from about 3 nm to about 5 nm in the Z-direction.

Referring to FIGS. 19A to 19G, gate structures 190A and 190B are formed in the gate trenches 168A and 168B, respectively, in accordance with some embodiments. FIGS. 19A, 19B, and 19E are cross-sectional views of the semiconductor structure 100A along lines A-A′, B-B′, and E-E′ of FIG. 2A, respectively. FIGS. 19C, 19D, and 19F are cross-sectional views of the semiconductor structure 100B along lines C-C′, D-D′, and F-F′ of FIG. 2B, respectively. The line E-E′ is parallel to the line B-B′, and the cross-sectional view of FIG. 19E shows the source/drain features 170A, while the cross-sectional view of FIG. 19B shows the gate structures 190A and the semiconductor layers 108A. Similarly, the line F-F′ is parallel to the line D-D′, and the cross-sectional view of FIG. 19F shows the source/drain features 170B, while the cross-sectional view of FIG. 19D shows the gate structures 190B and the semiconductor layers 108B. FIG. 19G is a partial enlarged cross-sectional view of the stack 186 of the semiconductor structure 100B shown in FIG. 19D.

In some embodiments, the gate structures 190A and 190B extend in the Y-direction. In some embodiments, the source/drain features 170A are formed on opposite sides of the gate structures 190A in the X-direction, as shown in FIG. 19A. In some embodiments, the source/drain features 170B are formed on opposite sides of the gate structures 190B in the X-direction, as shown in FIG. 19C.

In some embodiments, the gate structures 190A each includes an interfacial layer 192A formed on the surfaces of the semiconductor layers 108A to wrap around the exposed semiconductor layers 108A, and formed on the exposed surfaces of the base fins 102A1 and 102A2. In some embodiments, the gate structures 190B each includes an interfacial layer 192B formed on the exposed surfaces of the semiconductor layers 108B, the epitaxial layers 162, the base portions 184B, and the base fins 102B1 and 102B2, as shown in FIGS. 19C, 19D, and 19G. In some embodiments, the interfacial layers 192A and 192B may include a dielectric material such as SiO₂, HfSiO, or SiON. The interfacial layers 192A and 192B may be formed by chemical oxidation, thermal oxidation, CVD, PVD, ALD, HDPCVD, MOCVD, RPCVD, PECVD, LPCVD, ALCVD, APCVD, FCVD, and/or other suitable method. In some embodiments, the interfacial layers 192A and 192B have a thickness in a range from about 1 nm to about 1.5 nm.

In some embodiments, the gate structures 190A each includes a gate dielectric layer 194A and a gate electrode layer 196A over the gate dielectric layer 194A. In some embodiments, the gate dielectric layers 194A are formed on the interfacial layers 192A to wrap around the semiconductor layers 108A. In further embodiments, the gate dielectric layers 194A are also formed on the hard masks 110A to wrap around the hard masks 110A. In some embodiments, the gate dielectric layers 194A are also formed on the sidewalls of the inner spacers 146 and the gate spacers 132A, and over the top surfaces of the isolation structure 118 and interfacial layers 192A formed on the base fins 102A1 and 102A2.

In some embodiments, the gate structures 190B each includes a gate dielectric layer 194B and a gate electrode layer 196B over the gate dielectric layer 194B. In some embodiments, the gate dielectric layers 194B are formed on the interfacial layers 192B and the exposed surfaces of the dielectric layers 160 to wrap around the stacks 186. In some embodiments, the gate dielectric layers 194B are also formed on the sidewalls of the gate spacers 132B, the hard masks 110B, and the remaining portions of the topmost dielectric layers 160 that are over the topmost semiconductor layers 108B and below the gate spacers 132B, and over the top surfaces of the isolation structure 118 and the interfacial layers 192B formed on the base portions 184B and the base fins 102B1 and 120B2.

The gate dielectric layers 194A and 194B may include a dielectric material, such as SiOCN, SiOC, SiCN, SiO₂, SiN, SiC, or other suitable materials. In some embodiments, the gate dielectric layers 194A and 194B may include a high-k dielectric material that has a dielectric constant greater than a dielectric constant of SiO₂, which is approximately 3.9. For example, the gate dielectric layers 194A and 194B may include hafnium oxide (HfO₂), which has a dielectric constant in a range from about 18 to about 40. Alternatively, the gate dielectric layers 194A and 194B may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba, Sr) TiO₃ (BST), Al₂O₃, Si₃N₄, SiON, combinations thereof, or other suitable materials. The gate dielectric layers 194A and 194B may be formed by CVD, PVD, ALD, HDPCVD, MOCVD, RPCVD, PECVD, LPCVD, ALCVD, APCVD, FCVD, oxidation, and/or other suitable methods.

In some embodiments, the gate electrode layers 196A are formed to fill the remaining spaces of the gate trenches 168A, and over the gate dielectric layers 194A in such a way that the gate electrode layers 196A wrap around the gate dielectric layer 194A, the interfacial layers 192A, and the semiconductor layers 108A. In some embodiments, the gate electrode layers 196B are formed to fill the remaining spaces of the gate trenches 168B, and over the gate dielectric layers 194B in such a way that the gate electrode layers 196B wrap around the gate dielectric layer 194B, the interfacial layers 192B, and the stacks 186, wherein the stacks include the semiconductor layers 108B, the dielectric layers 160, the epitaxial layers 162, and the base portions 184B.

The gate electrode layers 196A and 196B each may include a single layer or a multi-layer structure. In some embodiments, the gate electrode layers 196A and 196B each may include a capping layer, a barrier layer, work function metal layers, and a fill material. The gate electrode layers 196A and 196B may be formed using a deposition process such as CVD, PVD, ALD, HDPCVD, MOCVD, RPCVD, PECVD, LPCVD, ALCVD, APCVD, FCVD, or the like, although any suitable deposition process may be used. The capping layer may be formed of a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The barrier layer may be formed of a material different from the capping layer. In some embodiments, the barrier layer may be formed of a material such as one or more layers of a metallic material. For example, the metallic material may be TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The work function layers may include conductive materials tuned to have a desired work function (e.g., an n-type work function or a p-type work function), such as n-type work function materials and/or p-type work function materials. In some embodiments, the n-type and p-type work function metal layers may include a material such as such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the fill material may include a suitable conductive material, such as Al, W, and/or Cu.

In some embodiments, the gate structures 190B are in direct contact with the top surfaces of the stacks 186. In other words, the gate structures 190B are in direct contact with top surfaces of the upper epitaxial layers 162A formed on the upper surfaces of the topmost semiconductor layers 108B, as shown in FIGS. 19C, 19D, and 19G. In some embodiments, the gate spacers 132B are separated from the upper epitaxial layers 162A formed on the upper surfaces of the topmost semiconductor layers 108B by the remaining portions of the hard masks 110B and the topmost dielectric layers 160. In other words, the remaining portions of the hard masks 110B and the topmost dielectric layers 160 that are over the topmost semiconductor layers 108B are between the gate spacers 132B and the top surfaces of the upper epitaxial layers 162A formed on the upper surfaces of the topmost semiconductor layers 108B, as shown in FIGS. 19C and 19D.

In some embodiments, since the semiconductor layers 108B and the epitaxial layers 162 of the semiconductor structure 100B have smaller widths than the widths of the semiconductor layers 108A of the semiconductor structure 100A in the Y-direction, the combinations of the semiconductor layers 108B and the epitaxial layers 162 may be referred to as nanowire structures, and the semiconductor layers 108A may be referred to as nanosheet structures. Furthermore, since the stacks 186 include the dielectric layers 160 interposed between the semiconductor layers 108B, the stacks 186 may be referred to as hybrid nanowire structures.

As described above with reference to FIGS. 17A to 17D, the trimming process applied on the semiconductor layers 108B may reduce the widths of the semiconductor layers 108B. In this way, the widths of the active regions corresponding to the semiconductor layers 108B are reduced. As a result, since the widths of the active regions are reduced, the number of the active regions in a given area can be increased, thereby increasing the device density, while the power efficiency is also improved due to the reduced widths of the active regions.

As described above with reference to FIGS. 11A to 11D, the epitaxial growth process forms the epitaxial layers 156 on surfaces of the semiconductor layers 108B, wherein the epitaxial layers 156 are fabricated into the upper epitaxial layers 162A and the lower epitaxial layers 162B during the fabrication stage shown in FIGS. 13A to 13D. The upper epitaxial layers 162A and the lower epitaxial layers 162B formed on the upper and lower surfaces of the semiconductor layers 108B may increase the cross-sectional areas of the nanostructures in the vertical direction (e.g., Z-direction). In this way, the increased cross-sectional areas can compensate the on-current decreased due to the trimming process. Furthermore, the increased cross-sectional areas also improve the quality of source/drain features epitaxially grown from the nanostructures, so that the source/drain features can be fully strained.

As described above with reference to FIGS. 13A to 13D, the dielectric layers 160 formed between the nanostructures (each including the semiconductor layers 108B, the upper epitaxial layers 162A, and the lower epitaxial layers 162B) may connect the nanostructure with each other. Since the dielectric layers 160 are filled between the nanostructures, the areas of metal gates (e.g., the gate structures 190B) are reduced equivalently. As a result, the parasitic capacitance can be reduced.

As shown in FIGS. 1 to 19F, the fabrication process of the semiconductor structure with nanostructure trimmed by the trimming process (e.g., the semiconductor structure 100B) may be compatible with the fabrication process of the semiconductor structure without the trimming process (e.g., the semiconductor structure 100A). As a result, the process flexibility can be improved. For example, the first type of transistors desiring wider active regions and the second type of transistors desiring narrower active regions may be formed in the same chip, even in the same cell.

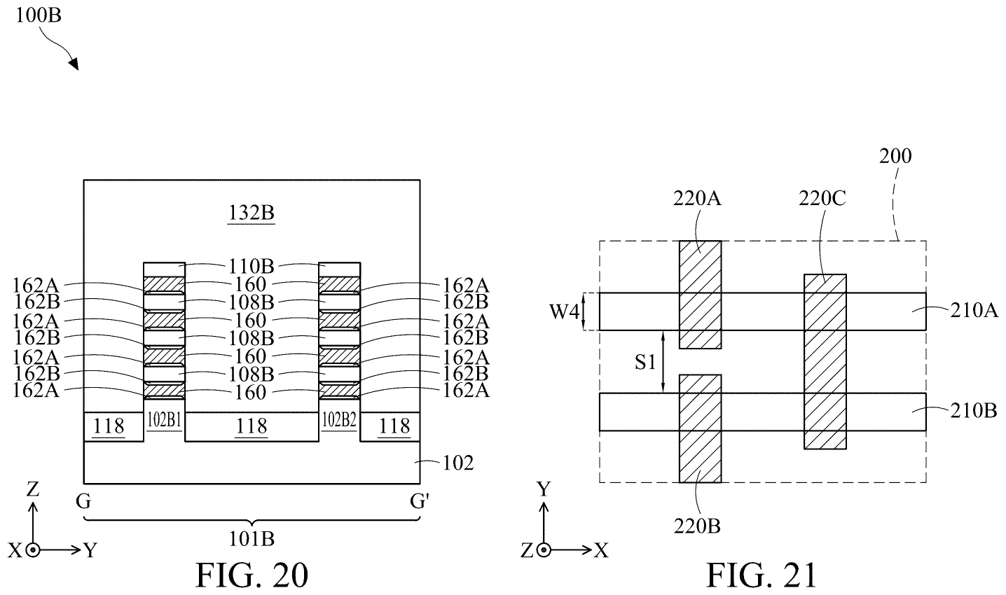

FIG. 20 is a cross-sectional view of the semiconductor structure 100B along line G-G′ of FIG. 19C, in accordance with some embodiments. The line G-G′ is parallel to the line D-D′ (for the purpose of clarity, line D-D′ is also shown in FIG. 19C), and the cross-sectional view along the G-G′ (i.e., FIG. 20) shows the gate spacers 132B and the semiconductor layers 108B covered by the gate spacers 132B, while the cross-sectional view along line D-D′ (i.e., FIG. 19D) shows the gate structures 190B and the semiconductor layers 108B covered by the gate structures 190B.

In some embodiments, each of the second semiconductor layers 108B, the dielectric layers 160, the upper epitaxial layers 162A, and the lower epitaxial layers 162B includes a middle portion covered by the gate structure 190B, and two end portions covered by the gate spacers 132B. The two end portion are located on opposite sides of the middle portion in the X-direction. For example, the cross-sectional view of the middle portions is as shown in FIG. 19D, and the cross-sectional view of the end portions is as shown in FIG. 20.

In some embodiments, since the middle portions are covered by the gate structures 190B that are formed in the gate trenches 168B, the middle portions of the of the second semiconductor layers 108B, the dielectric layers 160, the upper epitaxial layers 162A, and the lower epitaxial layers 162B have undergone the trimming process described above with reference to FIGS. 17A to 17D. As such, the middle portions have smaller widths than the end portions covered by the gate spacers 132B. In some embodiments, for the second semiconductor layers 108B, the dielectric layers 160, the upper epitaxial layers 162A, and the lower epitaxial layers 162B, the middle portions have smaller widths than the end portions, as shown in FIGS. 19D and 20. In some embodiments, in the region shown in FIG. 20, since the hard masks 110B and the topmost dielectric layers 160 are covered by the gate spacers 132B, the hard masks 110B and the topmost dielectric layers 160 are remained.

FIG. 21 is a schematic layout of an exemplary standard cell 200, in accordance with some embodiments of the present disclosure. It should be noted that, for the purpose of simplicity and clarity, FIG. 21 only illustrates the active regions and the gate structures. In some embodiments, the standard cell 200 includes active regions 210A and 210B (may be collectively referred to as the active regions 210) that extend lengthwise in the X-direction and are arranged (separated from each other) in the Y-direction. Each of the active regions 210 includes channel regions, source regions, and drain regions of transistors. In some embodiments, the standard cell 200 includes gate structures 220A to 220C (may be collectively referred to as the gate structures 220) that extend lengthwise in the Y-direction. In some embodiments, the gate structures 220A to 220C are engaged with the channel regions of the respective active regions 210A and 210B, and disposed between respective source/drain regions of the active regions 210A and 210B to form transistors.

In some embodiments, the standard cell 200 can be implemented in a manner of the semiconductor structure 100B. That is, the semiconductor layers 108B undergone the trimming process (see FIGS. 17C to 17D) can be applied to the active regions 210 of the standard cell 200. That is, the active regions 210 may be formed by the processes shown in FIGS. 1 to 19F described previously. In this way, the widths W4 of the active regions 210 in the Y-direction can be reduced. In the case of the spacing S1 between the active regions 210A and 210B is fixed, the reduced widths W4 can decrease the area of the standard cell 200, thereby increasing the number of standard cells 200 in a given area. That is, the device density can be increased. For example, when the width W4 is reduced from about 8˜13 nm to about 4˜6 nm, the device density can be increased by at least 20%.

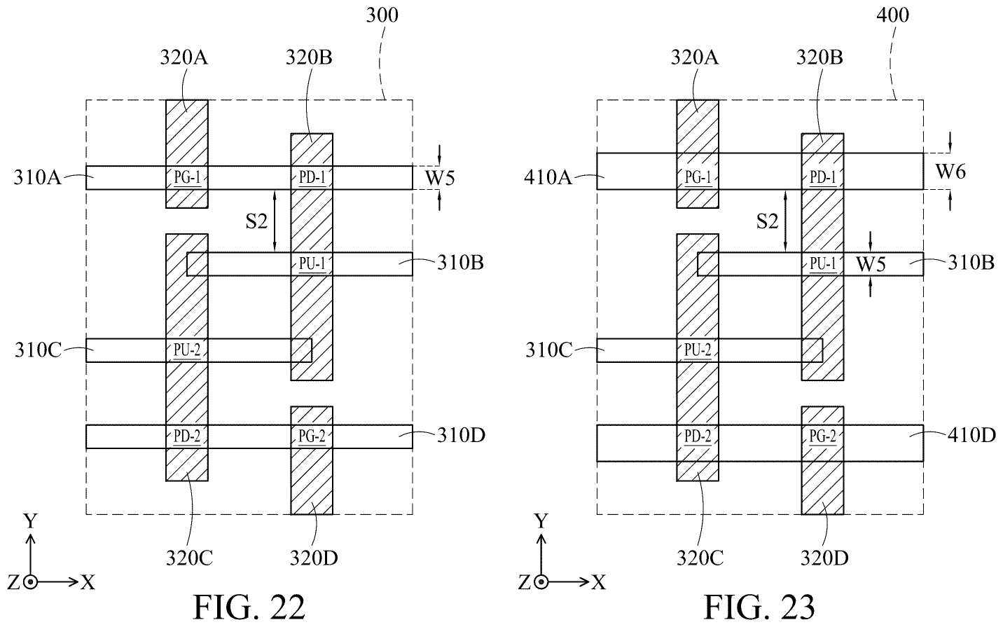

FIG. 22 is a schematic layout of an exemplary static random access memory (SRAM) cell 300, in accordance with some embodiments of the present disclosure. It should be noted that, for the purpose of simplicity and clarity, FIG. 22 only illustrates the active regions and the gate structures. In some embodiments, the SRAM cell 300 includes active regions 310A to 310D (may be collectively referred to as the active regions 310) that extend lengthwise in the X-direction and are arranged (separated from each other) in the Y-direction. Each of the active regions 310 includes channel regions, source regions, and drain regions of transistors. In some embodiments, the SRAM cell 300 includes gate structures 320A to 320C (may be collectively referred to as the gate structures 320) that extend lengthwise in the Y-direction.

In some embodiments, the gate structure 320A extends across and engages with the active region 310A to form a pass-gate transistor PG-1; the gate structure 320B extends across and engages with the active regions 310A and 310B to form a pull-down transistor PD-1 and a pull-up transistor PU-1, respectively; gate structure 320C extends across and engages with the active regions 310C and 310D to form a pull-up transistor PU-2 and a pull-down transistor PD-2, respectively; and the gate structure 320D extends across and engages with the active region 310D to form a pass-gate transistor PG-2.

In some embodiments, the SRAM cell 300 can be implemented in a manner of the semiconductor structure 100B. That is, the semiconductor layers 108B undergone the trimming process (see FIGS. 17C to 17D) can be applied to the active regions 310 of the SRAM cell 300. In this way, the widths W5 of the active regions 310 in the Y-direction can be reduced. In the case of the spacings S2 between the active regions 310 are fixed, the reduced widths W5 can decrease the area of the SRAM cell 300, thereby increasing the number of SRAM cells 300 in a given area. That is, the device density can be increased. For example, when the width W5 is reduced from about 8˜13 nm to about 4˜6 nm, the device density can be increased by at least 15%.

FIG. 23 is a schematic layout of an exemplary SRAM cell 400, in accordance with some embodiments of the present disclosure. It should be noted that, for the purpose of simplicity and clarity, FIG. 23 only illustrates the active regions and the gate structures. The SRAM cell 400 is similar to the SRAM cell 300, except the active regions 310A and 310D shown in FIG. 22 are replaced by the active regions 410A and 410D shown in FIG. 23, respectively. In some embodiments, since the SRAM cell 400 desires higher current than the SRAM cell 300, the widths of the active regions for the pass-gate transistors and pull-down transistors are greater than the widths of the active regions for the pull-up transistors. For example, the widths W6 of the active regions 410A and 410D are greater than the widths W5 of the active regions 310B and 310C, as shown in FIG. 23.

In some embodiments, since the SRAM cell 400 desires higher current, the widths W6 of the active regions 410A and 410D should remain unchanged and can be implemented in a manner of the semiconductor structure 100A, while the widths W5 of the active regions 310B and 310C can be reduced in a manner of the semiconductor structure 100B. That is, the semiconductor layers 108B undergone the trimming process (see FIGS. 17C to 17D) can be applied to the active regions 310B and 310C of the SRAM cell 400. In this way, the widths W5 of the active regions 310B and 310C in the Y-direction can be reduced. In the case of the spacings S2 between the active regions 410A, 310B, 310C, and 410D are fixed, the reduced widths W5 can decrease the area of the SRAM cell 400, thereby increasing the number of SRAM cells 400 in a given area. That is, the device density can be increased. For example, when the width W6 is 27 nm and the width W5 is reduced from about 8˜13 nm to about 4˜6 nm, the device density can be increased by at least 5%.

The embodiments disclosed herein relate to semiconductor structures and their forming methods, and more particularly to methods and semiconductor structures that include performing a trimming process on the nanostructures to reduce the width of active region, thereby increasing the device density and improving power efficiency. Furthermore, an additional epitaxial process is performed on the nanostructures, so that the areas of the nanostructures in the vertical direction can be increased. The increased areas of the nanostructures can improve the quality of source/drain features epitaxially grown form the nanostructures. Moreover, dielectric layers are formed between the nanostructures to reduce the area of metal gate equivalently, so as to reduce the parasitic capacitance.

In one exemplary aspect, the present disclosure is directed to a method of forming a semiconductor structure. The method includes forming a fin structure including first semiconductor layers and second semiconductor layers that are alternately stacked over a substrate; forming a dummy gate structure on the fin structure; and forming source/drain trenches on opposite sides of the dummy gate structure and in the fin structure. The method further includes removing the first semiconductor layers through the source/drain trenches to form cavities; epitaxially growing epitaxial layers on surfaces of the second semiconductor layers exposed in the cavities and the source/drain trenches; and forming dielectric layers to fill the cavities, such that the dielectric layers are between the second semiconductor layers, between the substrate and a bottommost one of the second semiconductor layers, and over a topmost one of the second semiconductor layers. The method further includes forming source/drain features in the source/drain trenches; removing the dummy gate structure to form a gate trench; trimming the second semiconductor layers and the dielectric layers through the gate trench; and forming a gate structure in the gate trench.

In another exemplary aspect, the present disclosure is directed to a method of forming a semiconductor structure. The method includes forming a first fin structure and a second fin structure in a first region and a second region of a substrate, respectively. The first fin structure includes first semiconductor layers and second semiconductor layers alternately stacked, and the second fin structure includes third semiconductor layers and fourth semiconductor layers alternately stacked. The method further includes forming first source/drain trenches in the first fin structure; removing the first semiconductor layers through the first source/drain trenches to form first cavities; and forming dielectric interposers in the first cavities. The method further includes forming second source/drain trenches in the second fin structure; removing the third semiconductor layers through the second source/drain trenches to form second cavities; and forming dielectric layers in the second cavities. The method further includes forming first source/drain features and second source/drain features in the first source/drain trenches and the second source/drain trenches, respectively; partially removing the dielectric layers; removing the dielectric interposers; and forming a first gate structure between the first source/drain features and a second gate structure between the second source/drain features.

In yet another exemplary aspect, the present disclosure is directed to a semiconductor structure. The semiconductor structure includes a first transistor in a first region of a substrate and a second transistor in a second region of the substrate. The first transistor includes first nanostructures vertically spaced apart from each other in a first direction, a first gate structure wrapped around each of the first nanostructures, and first source/drain features attached to opposite sides of the first nanostructures in a second direction that is perpendicular to the first direction. The second transistor includes a stack including second nanostructures and dielectric layers that are alternately stacked in the first direction, a second gate structure wrapped around the stack, and second source/drain features attached to opposite sides of the stack in the second direction. In a third direction that is perpendicular to the first direction and the second direction, a first width of the first nanostructures is greater than a second width of the second nanostructures, and the second width is greater than a third width of the dielectric layers.

In yet another exemplary aspect, the present disclosure is directed to a method of forming a semiconductor structure. The method includes forming a fin structure over a substrate; forming a dummy gate structure on the fin structure; and forming gate spacers on opposite sides of the dummy gate structure. The fin structure includes first semiconductor layers and second semiconductor layers that are alternately stacked, and includes a hard mask on a topmost one of the first semiconductor layers. The method further includes removing the first semiconductor layers to form cavities; and forming dielectric layers in the cavities, such that the dielectric layers are between the second semiconductor layers and between the substrate and a bottommost one of the second semiconductor layers. The method further includes removing the dummy gate structure to form a gate trench; performing a trimming process on the second semiconductor layers and the dielectric layers through the gate trench; and forming a gate structure in the gate trench.

In some embodiments, after forming the gate trench, each of the second semiconductor layers includes a middle portion exposed in the gate trench and end portions covered by the gate spacers. In the trimming process, the middle portion is trimmed while the end portions are covered by the gate spacers, such that after the trimming process, a middle width of the middle portion is smaller than an end width of the end portions.

In some embodiments, the method further includes forming source/drain trenches on opposite sides of the dummy gate structure and in the fin structure; and after forming the cavities, epitaxially growing epitaxial layers on surfaces of the second semiconductor layers exposed in the cavities and the source/drain trenches.

In some embodiments, the forming of the dielectric layers includes depositing a dielectric material layer in the cavities and the source/drain trenches; and removing portions of the dielectric material layer and portions of the epitaxial layers exposed in the source/drain trenches to form the dielectric layers in the cavities.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a fin structure over a substrate, wherein the fin structure comprises first semiconductor layers and second semiconductor layers that are alternately stacked;
forming a dummy gate structure on the fin structure;
forming source/drain trenches on opposite sides of the dummy gate structure and in the fin structure;
removing the first semiconductor layers through the source/drain trenches to form cavities;
epitaxially growing epitaxial layers on surfaces of the second semiconductor layers exposed in the cavities and the source/drain trenches;
forming dielectric layers to fill the cavities, such that the dielectric layers are between the second semiconductor layers, between the substrate and a bottommost one of the second semiconductor layers, and over a topmost one of the second semiconductor layers;
forming source/drain features in the source/drain trenches;
removing the dummy gate structure to form a gate trench;
trimming the second semiconductor layers and the dielectric layers through the gate trench; and
forming a gate structure in the gate trench.

2. The method of claim 1,
wherein the fin structure further comprises a hard mask on a topmost one of the first semiconductor layers,
wherein after the forming of the dielectric layers, a topmost one of the dielectric layers is between the hard mask and the topmost one of the second semiconductor layers.

3. The method of claim 2, wherein the trimming of the second semiconductor layers and the dielectric layers further comprises etching the hard mask and the topmost one of the dielectric layers.

4. The method of claim 1, wherein the forming of the dielectric layers comprises:
depositing a dielectric material layer in the cavities and the source/drain trenches; and
removing portions of the dielectric material layer and portions of the epitaxial layers exposed in the source/drain trenches to form the dielectric layers in the cavities.

5. The method of claim 4,
wherein after the removing of the portions of the epitaxial layers, remaining portions of the epitaxial layers comprises upper protrusions and lower protrusions,
wherein the upper protrusions are formed on upper surfaces of the second semiconductor layers, and the lower protrusions are formed on lower surfaces of the second semiconductor layers.

6. The method of claim 5, wherein the dielectric layers between the second semiconductor layers connect the second semiconductor layers with each other in a manner of connecting the lower protrusion of an upper one of the second semiconductor layers to the upper protrusion of an lower one of the second semiconductor layers.

7. The method of claim 1, wherein the forming of the gate structure comprises:
forming interfacial layers on the second semiconductor layers and the substrate;
forming a gate dielectric layer on the interfacial layers and the dielectric layers; and
forming a gate electrode layer on the gate dielectric layer.

8. The method of claim 1,
wherein the second semiconductor layers and the dielectric layers are vertically stacked in a first direction, and
wherein after the trimming, in a second direction perpendicular to the first direction, the second semiconductor layers have a first width in a range from about 4 nm to about 6 nm, and the dielectric layers have a second width in a range from about 2 nm to about 3.5 nm.

9. A method of forming a semiconductor structure, comprising:
forming a first fin structure and a second fin structure in a first region and a second region of a substrate, respectively, wherein the first fin structure comprises first semiconductor layers and second semiconductor layers alternately stacked, and the second fin structure comprises third semiconductor layers and fourth semiconductor layers alternately stacked;
forming first source/drain trenches in the first fin structure;
removing the first semiconductor layers through the first source/drain trenches to form first cavities;
forming dielectric interposers in the first cavities;
forming second source/drain trenches in the second fin structure;
removing the third semiconductor layers through the second source/drain trenches to form second cavities;
forming dielectric layers in the second cavities;
forming first source/drain features and second source/drain features in the first source/drain trenches and the second source/drain trenches, respectively;
partially removing the dielectric layers;
removing the dielectric interposers; and
forming a first gate structure between the first source/drain features and a second gate structure between the second source/drain features.

10. The method of claim 9, wherein the first gate structure wraps around each of the second semiconductor layers, and the second gate structure wraps around a stack comprising the fourth semiconductor layers and the dielectric layers between the fourth semiconductor layers.

11. The method of claim 9, further comprising:
trimming the fourth semiconductor layers, wherein after trimming, the fourth semiconductor layers have a smaller width than the second semiconductor layers.

12. The method of claim 11,
wherein the first fin structure further comprises a first hard mask on a topmost one of the first semiconductor layers, and the second fin structure further comprises a second hard mask on a topmost one of the third semiconductor layers,
wherein after the forming of the first gate structure, the first hard mask is wrapped around by the first gate structure,
wherein the trimming of the fourth semiconductor layers and the dielectric layers further comprises etching through the second hard mask.

13. The method of claim 9, further comprising:
before forming the dielectric layers, epitaxially growing first epitaxial layers on surfaces of the second semiconductor layers exposed in the second cavities and the second source/drain trenches,
wherein the forming of the dielectric layers is performed after the epitaxially growing of the first epitaxial layers.

14. The method of claim 13, wherein the forming of the dielectric layers comprises:
depositing a dielectric material layer in the second cavities and the second source/drain trenches; and
removing portions of the dielectric material layer and portions of the first epitaxial layers exposed in the second source/drain trenches to form the dielectric layers in the second cavities.

15. The method of claim 14,
wherein after the removing of the portions of the first epitaxial layers, remaining portions of the first epitaxial layers comprises upper protrusions and lower protrusions,
wherein the upper protrusions are formed on upper surfaces of the fourth semiconductor layers, and the lower protrusions are formed on lower surfaces of the fourth semiconductor layers.

16. The method of claim 9, further comprising:
partially recessing the dielectric interposers exposed in the first source/drain trenches to form inner spacer recesses; and
forming inner spacers in the inner spacer recesses.

17. A semiconductor structure, comprising:
a first transistor in a first region of a substrate, the first transistor comprising:
first nanostructures, vertically spaced apart from each other in a first direction;
a first gate structure, wrapped around each of the first nanostructures; and
first source/drain features, attached to opposite sides of the first nanostructures in a second direction that is perpendicular to the first direction;
a second transistor in a second region of the substrate, the second transistor comprising:
a stack comprising second nanostructures and dielectric layers that are alternately stacked in the first direction, wherein in a third direction that is perpendicular to the first direction and the second direction, a first width of the first nanostructures is greater than a second width of the second nanostructures, and the second width is greater than a third width of the dielectric layers;
a second gate structure, wrapped around the stack; and
second source/drain features, attached to opposite sides of the stack in the second direction.

18. The semiconductor structure of claim 17,
wherein each of the second nanostructures comprises an upper protrusion extending upward and a lower protrusion extending downward in the first direction,
wherein the dielectric layers connect the second nanostructures with each other in a manner of connecting the lower protrusion of an upper one of the second nanostructures to the upper protrusion of an lower one of the second nanostructures.

19. The semiconductor structure of claim 17, wherein in the first direction, the first nanostructures have a first thickness in a range from about 4 nm to about 6 nm, the second nanostructures have a second thickness in a range from about 9 nm to about 11 nm, and the dielectric layers have a third thickness in a range from about 3 nm to about 5 nm.

20. The semiconductor structure of claim 17,
wherein the second transistor further comprises second gate spacers formed on opposite sides of the second gate structure,
wherein the second gate structure is in direct contact with a top surface of a topmost one of the second nanostructures,
wherein a hard mask and an additional dielectric layer separated the second gate spacers from the top surface of the topmost one of the second nanostructures.
